(19) United States
(12) Patent Application Publication
(10) Pub. No.: US 2011/0300694 A1
(43) Pub. Date: Dec. 8, 2011

(54) ELECTRODE CIRCUIT, FILM FORMATION DEVICE, ELECTRODE UNIT, AND FILM FORMATION METHOD

(75) Inventors: Koichi Matsumoto, Chigasaki-shi (JP); Hidenori Yoda, Chigasaki-shi (JP); Satohiro Okayama, Chigasaki-shi (JP); Yawara Morioka, Chigasaki-shi (JP); Taro Yajima, Chigasaki-shi (JP)

(73) Assignee: ULVAC, INC., Chigasaki-shi (JP)

(21) Appl. No.: 13/128,430

(22) PCT Filed: Nov. 12, 2009
(86) PCT No.: PCT/JP2009/006059

§ 371 Date: Aug. 3, 2011

(30) Foreign Application Priority Data
Nov. 12, 2008 (JP) 2008-289590

(51) Int. Cl. C23C 16/509; H01L 21/20; C30B 28/12

(52) U.S. Cl. 438/488; 118/723 MP; 117/108; 257/E21.09

(57) ABSTRACT

An electrode circuit for plasma CVD includes: an alternating-current source; a matching circuit that is connected to the alternating-current source; and parallel plate electrodes that are constituted of a pair of an anode electrode and a cathode electrode, in which the anode electrode and the cathode electrode are arranged such that electrode surfaces of the anode electrode and the cathode electrode face each other. The matching circuit, the parallel plate electrodes, and plasma generated by the parallel plate electrodes form a balanced circuit.

### TECHNICAL FIELD

The present invention relates to an electrode circuit, a film formation device, an electrode unit, and a film formation method.

Priority is claimed on Japanese Patent Application No. 2008-289590, filed on Nov. 12, 2008, the contents of which are incorporated herein by reference.

### BACKGROUND ART

Currently, monocrystalline Si and polycrystalline Si are mostly used for solar cells and there is a concern about a shortage of Si. In recent years, there has been increasing demand for a thin-film solar cell in which a thin Si layer is formed at a low cost and is less likely to cause a material shortage. In addition, in recent years, there has been increasing demand for a tandem thin-film solar cell in which an a-Si layer and a μc-Si (microcrystalline silicon) layer are laminated to improve photoelectric conversion efficiency (hereinafter, simply referred to as conversion efficiency) in addition to a conventional thin-film solar cell including only the a-Si (amorphous silicon) layer. In many cases, a plasma CVD apparatus is used to form the thin Si layer (semiconductor layer) of the thin-film solar cell.

When the conversion efficiency of the thin-film solar cell is considered, the μc-Si layer of the tandem solar cell needs to be formed with a thickness (approximately 1.5 μm) that is approximately five times more than that of the a-Si layer. In addition, there is a limitation in increasing the deposition rate of the μc-Si layer since a high-quality microcrystalline layer needs to be uniformly formed. Therefore, in order to solve these problems, for example, it is necessary to increase the number of batch processes to improve productivity. That is, a film formation device capable of achieving a low deposition rate and high throughput is required.

A CVD apparatus has been proposed in which a plurality of radio frequency electrodes (cathodes) is provided in one film forming chamber and radio frequency power supplies (RF power supplies) and matching circuits corresponding to the number of radio frequency electrodes are provided (for example, see Patent Document 1). In the CVD apparatus disclosed in Patent Document 1, a substrate on which a film will be formed is arranged in the film forming chamber together with an opposite electrode (anode) so as to face each radio frequency electrode. The film forming chamber is depressurized to a vacuum and a film forming gas is supplied into the film forming chamber. The radio frequency electrode includes a heater for heating the substrate. The film forming gas (radical) decomposed by plasma reaches the film forming surface of the substrate heated by the heater and a desired film is formed on the film forming surface of the substrate.

### PATENT DOCUMENTS

[Patent Document 1] Japanese Unexamined Patent Application, First Publication No. 2005-158980

### DISCLOSURE OF THE INVENTION

### Problem that the Invention is to Solve

In the above-described conventional CVD apparatus, such as the above-mentioned CVD apparatus, the radio frequency electrode is connected to the radio frequency power supply (RF power supply) through the matching circuit which is an unbalanced circuit. That is, in the CVD apparatus, a matching box including the matching circuit, a chamber forming the film forming chamber, a carrier for transporting the substrate, a mask provided at the edge of the substrate, and the anode are electrically connected to the ground and radio-frequency power is input to the radio frequency electrode.

As such, when the matching circuit is an unbalanced circuit, a current flows between the cathode and the chamber in addition to between the cathode and the anode. Therefore, discharge also occurs between the cathode and the chamber and a film is formed on the inner wall of the chamber. As such, when a film is formed on the inner wall of the chamber, the film peels off due to an impact during the transport of the carrier or during a film forming process, which causes the generation of particles.

In addition, when the mask and the anode are electrically connected to the ground, a thick film is formed in the vicinity of the mask that is close to the cathode. As a result, the thickness of the film formed on the substrate is not uniform.

In the CVD apparatus disclosed in Patent Document 1 in which a plurality of radio frequency electrodes is arranged in one film forming chamber and the matching circuit is an unbalanced circuit, when one matching circuit is out of order due to, for example, a defect, the electrode balance (discharge balance) of other radio frequency electrodes is broken and the film formed on each substrate is not uniform.

The present invention has been made in view of the above-mentioned problems, and an object of the present invention is to provide an electrode circuit, a film formation device, an electrode unit, and a film formation method capable of forming uniform films on film forming surfaces of a plurality of substrates at the same time.

### Means for Solving the Problem

In order to solve the problems and achieve the object, the present invention adopts the followings.

(1) An electrode circuit of the present invention is an electrode circuit for plasma CVD includes: an alternating-current source; a matching circuit that is connected to the alternating-current source; and parallel plate electrodes that are constituted of a pair of an anode electrode and a cathode electrode, in which the anode electrode and the cathode electrode are arranged such that electrode surfaces of the anode electrode and the cathode electrode face each other. The matching circuit, the parallel plate electrodes, and plasma generated by the parallel plate electrodes form a balanced circuit.

According to the electrode circuit described (1) above, since the circuit including the matching circuit, the parallel plate electrodes, and the plasma generated by the parallel plate electrodes circuit is a balanced circuit, a current flows only between the parallel plate electrodes (a pair of the anode electrode and the cathode electrode). Therefore, plasma is generated only between the parallel plate electrodes. As a result, uniform plasma is generated between the parallel plate electrodes and it is possible to form a uniform film on the film forming surface of the substrate.

(2) In the electrode circuit according to (1) above, two sets of the parallel plate electrodes may be connected to one alternating-current source. The electrode surfaces of the anode electrodes of the two sets of parallel plate electrodes may be arranged in parallel so as to face each other, and the cathode electrodes of the two sets of parallel plate electrodes may be provided between the anode electrodes.

According to (2) above, since two sets of parallel plate electrodes are connected to one alternating-current source, it is possible to form films on two substrates at the same time. In addition, since the circuit including the matching circuit, the parallel plate electrodes, and the plasma generated by the parallel plate electrodes circuit is a balanced circuit, uniform plasma can be generated between the anode electrode and the cathode electrode. Therefore, when two substrates are arranged between the anode electrodes and the cathode electrodes, it is possible to form uniform films on the film forming surfaces of the two substrates at the same time.

(3) In the electrode circuit according to (2) above, the electrode surfaces of each of the cathode electrodes of the two sets of parallel plate electrodes may be one surface and the other surface of one cathode electrode.

According to (3) above, the size of the electrode circuit is reduced.

(4) The electrode circuit according to (1) above may include a plurality of the alternating-current sources. The matching circuit and one set of the parallel plate electrodes may be connected to each of the plurality of alternating-current sources. The electrode surfaces of the anode electrodes of a plurality of the parallel plate electrodes connected to the plurality of alternating-current sources may be arranged in parallel so as to face each other. The cathode electrodes of the parallel plate electrodes may be provided between the anode electrodes. An insulator may be provided between the cathode electrodes.

According to (4) above, since the parallel plate electrodes are connected to each of the plurality of alternating-current sources, it is possible to form films on two or more substrates at the same time. In addition, since the circuit including the matching circuit, the parallel plate electrodes, and the plasma generated by the parallel plate electrodes circuit is a balanced circuit, uniform plasma can be generated between the anode electrode and the cathode electrode. Therefore, when the substrates are arranged between the anode electrodes and the cathode electrodes, it is possible to form uniform films on the film forming surfaces of two or more substrates at the same time. Since the alternating-current source is provided for each set of parallel plate electrodes, it is possible to adjust a power supply output voltage for each alternating-current source and it is possible to generate uniform plasma between the parallel plate electrodes.

Since the insulator is provided between the cathode electrodes, voltages are applied to the cathode electrodes without any interference therebetween. Therefore, discharge occurs in a plurality of film formation spaces without any interference therebetween and it is possible to stably form a uniform film on each substrate.

(5) A film formation device of the present invention includes: a plurality of the electrode circuits according to any one of (1) to (4) above which is provided in one film forming chamber. In a plurality of the parallel plate electrodes in the plurality of electrode circuits, the electrode surfaces of the anode electrodes are arranged in parallel so as to face each other, and the cathode electrodes of the parallel plate electrodes are provided between the anode electrodes.

According to the film formation device described (5) above, since a circuit including the matching circuit, the parallel plate electrodes, and the plasma generated by the parallel plate electrodes circuit is a balanced circuit, a current flows only between the parallel plate electrodes (a pair of an anode electrode and a cathode electrode) and plasma is generated only between the parallel plate electrodes. Therefore, uniform plasma is generated between the parallel plate electrodes and it is possible to form a uniform film on the film forming surface of the substrate. Since the balanced circuit is formed, a current flows only between the anode electrode and the cathode electrode and no current theoretically flows between the cathode electrode and a chamber, which is a film forming chamber. Therefore, no discharge occurs at that position and it is possible to prevent a film being formed on the inner wall of the chamber. As a result, it is possible to prevent the generation of particles.

(6) An electrode unit of the present invention includes the electrode circuit according to any one of (1) to (4) above, and the electrode circuit is configured so as to be integrally attached to or detached from a film forming chamber.

According to the electrode unit described (6) above, since the electrode circuit is configured so as to be removable from the film forming chamber, it is possible to easily maintain the electrode unit.

(7) A film formation method of the present invention uses the film formation device according to (5) above. In the method, a mask provided at an edge of a substrate is electrically connected to a ground to form a film.

According to the film formation method described (7) above, since the mask is electrically connected to the ground, it is possible to form a uniform film on the film forming surface of the substrate.

### Effects of the Invention

According to the electrode circuit described (1) above, since the circuit including the matching circuit, the parallel plate electrodes, and the plasma generated by the parallel plate electrodes circuit is a balanced circuit, a current flows only between the parallel plate electrodes (a pair of the anode electrode and the cathode electrode). Therefore, plasma is generated only between the parallel plate electrodes. As a result, uniform plasma is generated between the parallel plate electrodes and it is possible to form a uniform film on the film forming surface of the substrate.

### BRIEF DESCRIPTION OF THE DRAWINGS

FIG. 1 is a cross-sectional view schematically illustrating an example of a thin-film solar cell manufactured by a film formation device according to a first embodiment of the present invention.

FIG. 2 is a plan view schematically illustrating an example of a thin-film solar cell manufacturing apparatus including the film formation device according to the first embodiment of the present invention.

FIG. 3A is a perspective view illustrating a film forming chamber of the thin-film solar cell manufacturing apparatus.

FIG. 3B is a perspective view illustrating the film forming chamber, as viewed from another angle.

FIG. 3C is a side view illustrating the film forming chamber.

FIG. 4A is a perspective view illustrating an electrode unit according to the first embodiment of the present invention.

FIG. 4B is a perspective view illustrating the electrode unit, as viewed from another angle.

FIG. 4C is a partial exploded perspective view illustrating the electrode unit.

FIG. 4D is a partial cross-sectional view illustrating a cathode unit and an anode unit of the electrode unit.

FIG. 5 is a diagram schematically illustrating an example of the structure of a matching circuit in an electrode circuit according to the present invention.

FIG. 6 is a circuit diagram illustrating the matching circuit.

FIG. 7 is a diagram illustrating the potential waveform of each electrode of the matching circuit shown in FIG. 6.

FIG. 8A is a perspective view illustrating an example of a loading-ejecting chamber of the thin-film solar cell manufacturing apparatus including the film formation device according to the present invention.

FIG. 8B is a perspective view illustrating the loading-ejecting chamber, as viewed from another angle.

FIG. 9 is a diagram schematically illustrating an example of the structure of a push-pull mechanism of the thin-film solar cell manufacturing apparatus including the film formation device according to the present invention.

FIG. 10A is a perspective view illustrating an example of a substrate replacement chamber of the thin-film solar cell manufacturing apparatus including the film formation device according to the present invention.

FIG. 10B is a front view illustrating the substrate replacement chamber.

FIG. 11 is a perspective view illustrating an example of a substrate storage holder of the thin-film solar cell manufacturing apparatus including the film formation device according to the present invention.

FIG. 12 is a perspective view illustrating an example of a carrier of the thin-film solar cell manufacturing apparatus including the film formation device according to the present invention.

FIG. 13 is a diagram (1) illustrating a process of a thin-film solar cell manufacturing method to which a film formation method according to the present invention is applied. FIG. 14 is a diagram (2) illustrating a process of the thin-film solar cell manufacturing method.

FIG. 15 is a diagram (3) illustrating a process of the thin-film solar cell manufacturing method.

FIG. 16 is a diagram (4) illustrating a process of the thin-film solar cell manufacturing method.

FIG. 17 is a diagram (5) illustrating a process of the thin-film solar cell manufacturing method.

FIG. 18A is a diagram illustrating the operation of a push-pull mechanism of the thin-film solar cell manufacturing apparatus including the film formation device according to the present invention.

FIG. 18B is a diagram illustrating the operation of the push-pull mechanism of the thin-film solar cell manufacturing apparatus including the film formation device according to the present invention.

FIG. 19 is a diagram (6) illustrating a process of the thin-film solar cell manufacturing method to which the film formation method according to the present invention is applied.

FIG. 20 is a diagram (7) illustrating a process of the thin-film solar cell manufacturing method.

FIG. 21 is a diagram (8) illustrating a process of the thin-film solar cell manufacturing method and is a cross-sectional view schematically illustrating the insertion of substrates into the electrode unit.

FIG. 22 is a diagram (9) illustrating a process of the thin-film solar cell manufacturing method.

FIG. 23 is a diagram (10) illustrating a process of the thin-film solar cell manufacturing method.

FIG. 24 is a diagram (11) illustrating a process of the thin-film solar cell manufacturing method and is a partial cross-sectional view illustrating the setting of substrates to the electrode unit.

FIG. 25 is a diagram (12) illustrating a process of the thin-film solar cell manufacturing method.

FIG. 26 is a diagram (13) illustrating a process of the thin-film solar cell manufacturing method.

FIG. 27 is a diagram (14) illustrating a process of the thin-film solar cell manufacturing method.

FIG. 28 is a diagram (15) illustrating a process of the thin-film solar cell manufacturing method.

FIG. 29 is a partial cross-sectional view illustrating a cathode unit and anodes included in a film formation device according to a second embodiment of the present invention.

FIG. 30 is a diagram schematically illustrating the structure of a matching circuit included in the film formation device.

FIG. 31 is a partial cross-sectional view illustrating a cathode unit and anodes included in a film formation device according to a third embodiment of the present invention.

### DESCRIPTION OF EMBODIMENTS

### First Embodiment

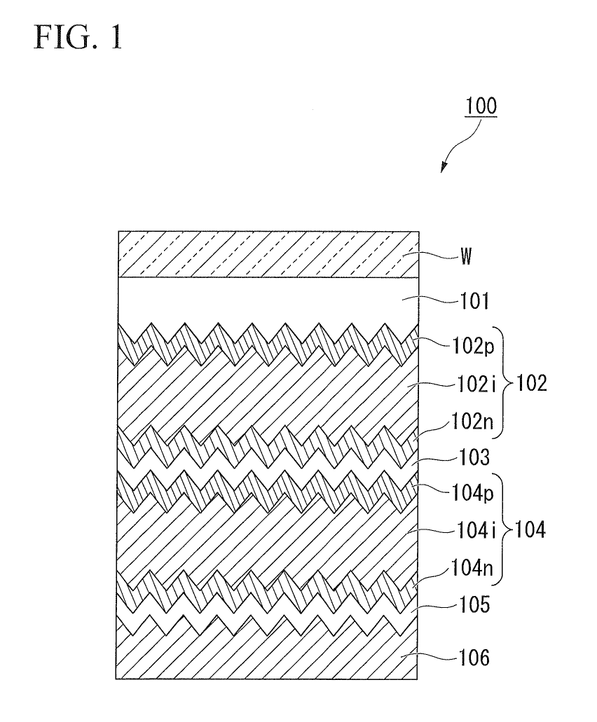

A film formation device (thin-film solar cell manufacturing apparatus) according to a first embodiment of the present invention will be described with reference to FIGS. 1 to 28.

### (Thin-Film Solar Cell)

FIG. 1 is a cross-sectional view schematically illustrating an example of a thin-film solar cell 100 manufactured by a thin-film solar cell manufacturing apparatus according to this embodiment. As shown in FIG. 1, the thin-film solar cell 100 includes: a substrate W (for example, a glass substrate) forming the surface of the thin-film solar cell; a top electrode 101 that is a transparent conductive film and is provided on the substrate W; a top cell 102 that is made of amorphous silicon; an intermediate electrode 103 that is a transparent conductive film and is provided between the top cell 102 and a bottom cell 104 which will be described below; a bottom cell 104 that is made of microcrystalline silicon; a buffer layer 105 that is a transparent conductive film; and a back electrode 106 that is a metal film. That is, the thin-film solar cell 100 is an amorphous silicon/microcrystalline silicon tandem solar cell. In the thin-film solar cell 100 with a tandem structure, the top cell 102 absorbs short-wavelength light and the bottom cell 104 absorbs long-wavelength light. In this way, power generation efficiency is improved.

The top cell 102 has a three-layer structure of a p layer (102p), an i layer (102i), and an n layer (102n) which are made of amorphous silicon (a-Si). The bottom cell 104 has a three-layer structure of a p layer (104p), an i layer (104i), and an n layer (104n) which are made of microcrystalline silicon (μc-Si).

In the thin-film solar cell 100 having the above-mentioned structure, when energy particles, which are called photons included in sunlight, reach the i layer, electrons and holes are generated by the photovoltaic effect. Among the electrons and holes, the electrons are moved to the n layer and the holes are moved to the p layer. The electrons and holes generated by the photovoltaic effect are extracted by the top electrode 101 and the back electrode 106. In this way, it is possible to convert optical energy into electric energy.

Since the intermediate electrode 103 is provided between the top cell 102 and the bottom cell 104, some of the light components that pass through the top cell 102 and reach the bottom cell 104 are reflected from the intermediate electrode 103 and are incident on the top cell 102 again. Therefore, the sensitivity characteristics of the cell are improved and power generation efficiency is improved.

Sunlight incident on the substrate W passes through each layer and is then reflected from the back electrode 106. The thin-film solar cell 100 has a texture structure for obtaining a prism effect of expanding the optical path of sunlight incident on the top electrode 101 and a light confinement effect in order to improve the conversion efficiency of optical energy.

### (Thin-Film Solar Cell Manufacturing Apparatus)

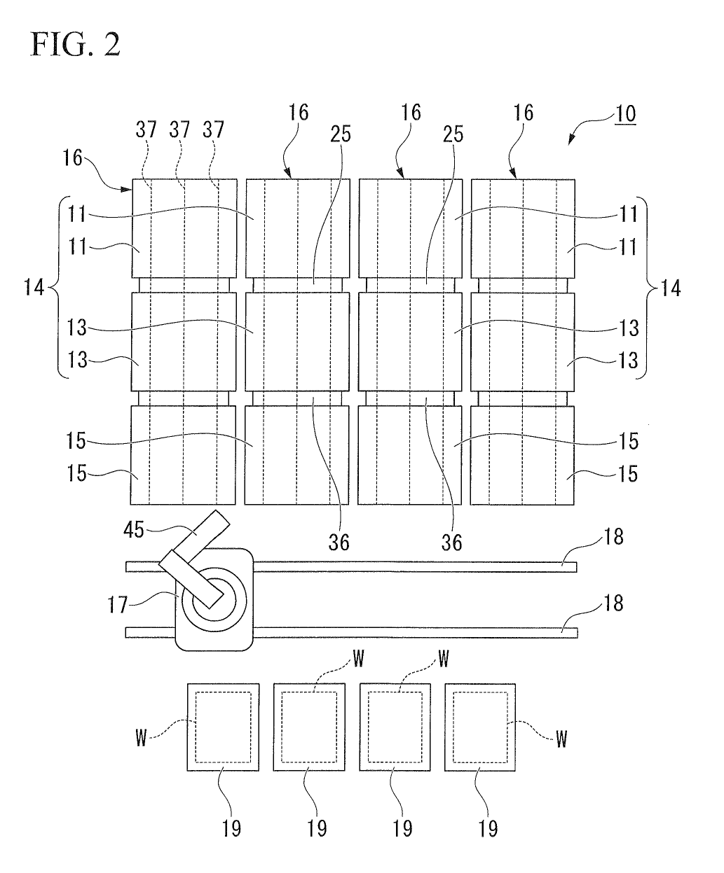

FIG. 2 is a plan view schematically illustrating the thin-film solar cell manufacturing apparatus (plasma CVD apparatus) according to the first embodiment of the present invention. As shown in FIG. 2, a thin-film solar cell manufacturing apparatus 10 includes film forming chambers 11 that can simultaneously form the bottom cells 104 (semiconductor layer) made of microcrystalline silicon on a plurality of substrates W using plasma CVD; loading-ejecting chambers 13 that can simultaneously store a pre-processed substrate W1 (substrate w) that is carried into the film forming chamber 11 and a post-processed substrate W2 (substrate w) that is carried out from the film forming chamber 11; substrate replacement chambers 15 that remove the pre-processed substrate W1 and the post-processed substrate W2 from a carrier 21 (see FIG. 12); a substrate replacement robot 17 that removes the substrate W from the carrier 21; and substrate storage holders 19 that store the substrates W to be transported to other processing chambers. In this embodiment, four substrate film formation lines 16 each having the film forming chamber 11, the loading-ejecting chamber 13, and the substrate replacement chamber 15 are provided. The substrate replacement robot 17 can be moved along rails 18 that are installed on the floor. In this way, one substrate replacement robot 17 can deliver or receive the substrates W to or from all of the substrate film formation lines 16. The film forming chamber 11 and the loading-ejecting chamber 13 are integrated into a substrate film formation module 14, and the substrate film formation module 14 has a sufficient size to be mounted on a vehicle, such as a truck. In the thin-film solar cell manufacturing apparatus according to this embodiment, deposition is performed with electrode surfaces (electrode surfaces of a cathode electrode and an anode electrode), which will be described below, being arranged in parallel to a film forming surface of the substrate W. In this case, deposition is performed with the electrode surfaces being arranged so as to be inclined at an angle of less than 45 degrees with respect to the gravity direction (this is the same as that in the following embodiments). That is, deposition is performed with the substrate W arranged substantially in the vertical direction (which will be described in detail below).

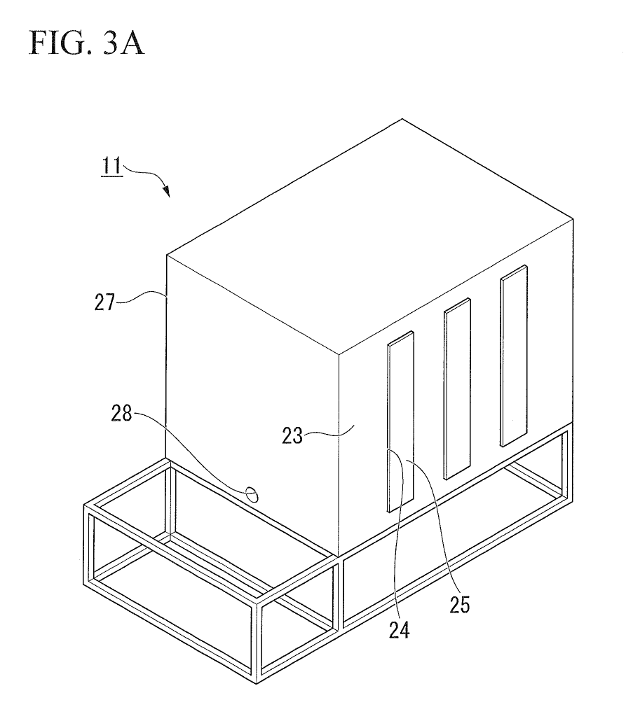

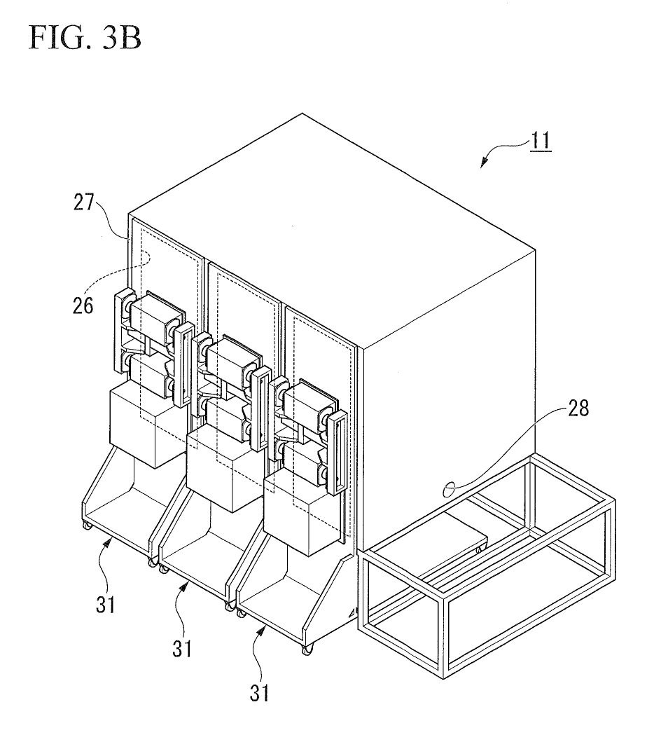

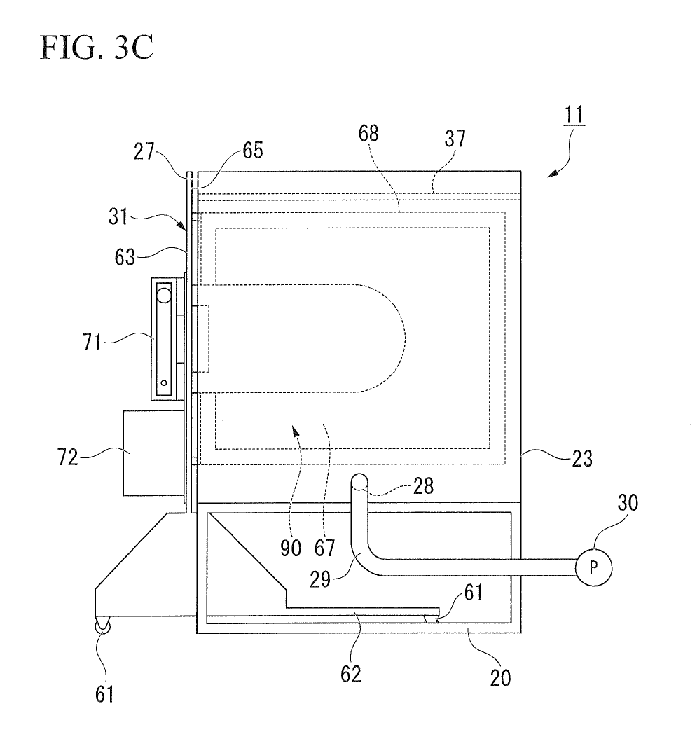

FIGS. 3A to 3C are diagrams schematically illustrating the structure of the film forming chamber. FIG. 3A is a perspective view illustrating the film forming chamber, FIG. 3B is a perspective view illustrating the film forming chamber, as viewed from an angle different from that in FIG. 3A, and FIG. 3C is a side view illustrating the film forming chamber.

As shown in FIGS. 3A to 3C, the film forming chamber 11 has a box shape. Three carrier transfer inlet ports 24 through which the carrier 21 having the substrate W loaded thereon can pass are formed in a first lateral surface 23 of the film forming chamber 11 connected to the loading-ejecting chamber 13. A shutter 25 that closes or opens the carrier transfer inlet port 24 is provided in each of the carrier transfer inlet ports 24. When the shutters 25 are closed, the carrier transfer inlet ports 24 are sealed airtight. Three electrode units 31 for forming a film on the substrate W are attached to a second lateral surface 27 of the film forming chamber 11 opposite to the first lateral surface 23. The electrode units 31 are removable from the film forming chamber 11. A vacuum pump 30 for evacuating the film forming chamber 11 is connected to a lower portion 28 of a third lateral surface of the film forming chamber 11 through an vacuuming pipe 29 (see FIG. 3C; not shown in FIGS. 3A and 3B).

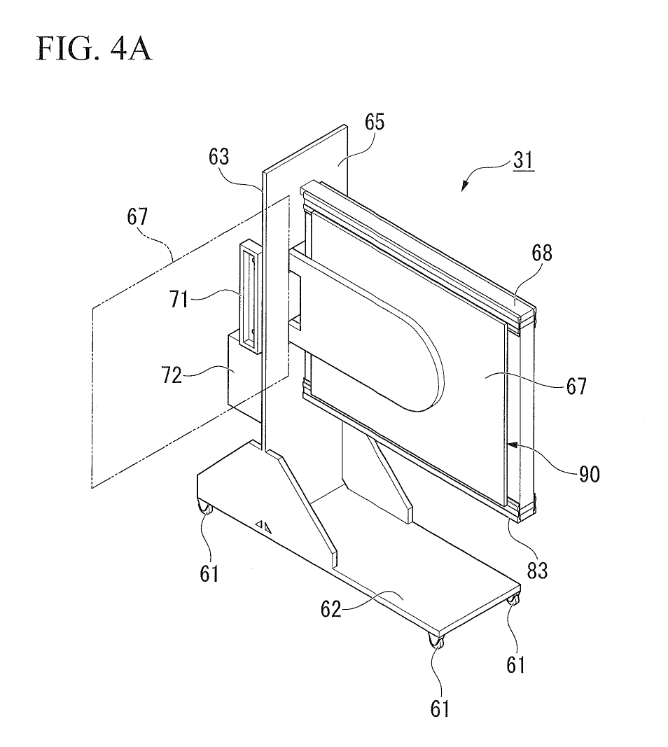

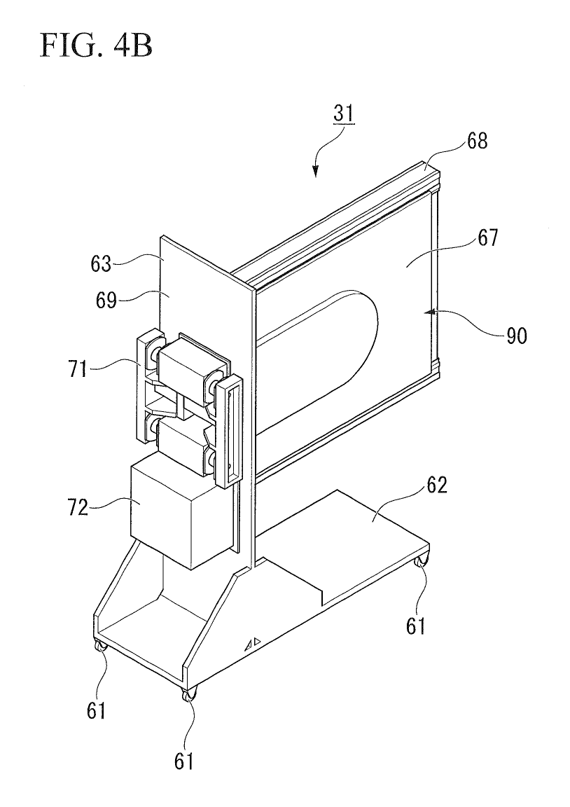

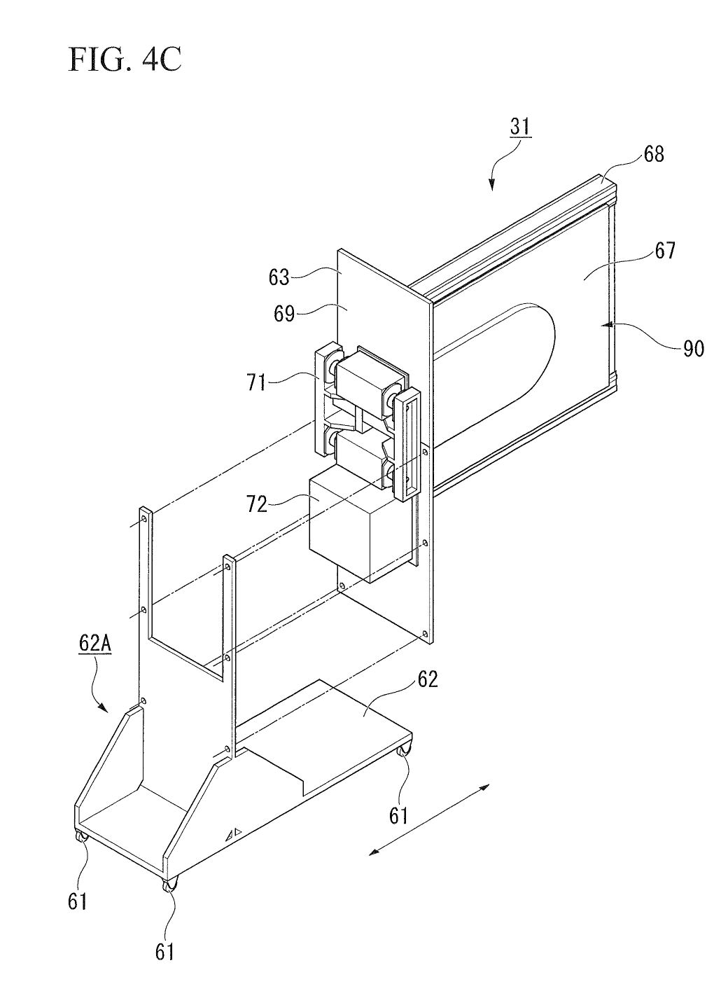

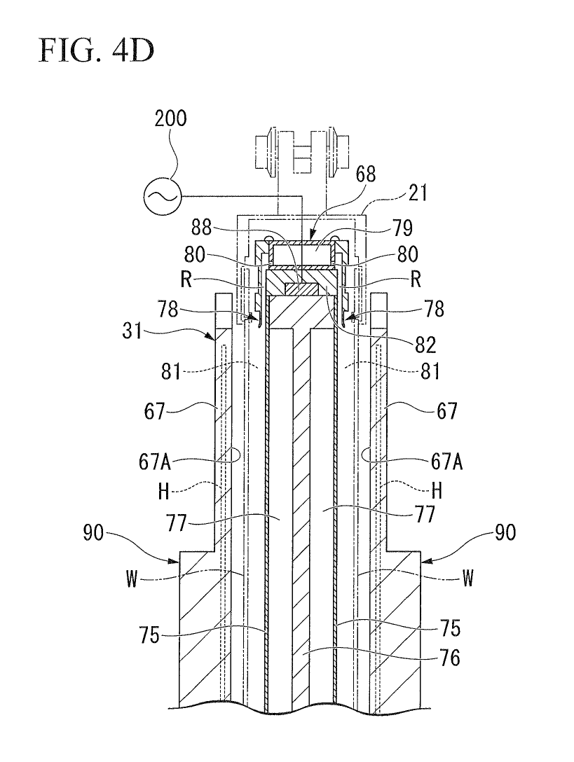

FIGS. 4A to 4D are diagrams schematically illustrating the structure of the electrode unit 31 which is provided in the thin-film solar cell manufacturing apparatus according to an embodiment of the present invention. FIG. 4A is a perspective view illustrating the electrode unit 31 and FIG. 4B is a perspective view illustrating the electrode unit 31, as viewed from an angle different from that in FIG. 4A. FIG. 4C is a partial exploded perspective view illustrating the electrode unit 31. FIG. 4D is a partial cross-sectional view illustrating a cathode unit and an anode unit (parallel plate electrodes) provided in the electrode unit 31.

The electrode units 31 can be attached or detached to or from three openings 26 formed in the second lateral surface 27 of the film forming chamber 11 (see FIG. 3B). Wheels 61 are provided at four corners of the bottom (bottom plate portion 62) of the electrode unit 31 and the electrode unit 31 can be moved on the floor. A side plate portion 63 is vertically provided on the bottom plate portion 62 having the wheels 61 attached thereto. The side plate portion 63 has a size capable of blocking the opening 26 formed in the second lateral surface 27 of the film forming chamber 11. That is, when the electrode unit 31 is attached to the film forming chamber 11, the side plate portion 63 forms a portion of the wall of the film forming chamber 11.

FIG. 4C shows a modification of the electrode unit 31. As shown in FIG. 4C, the bottom plate portion 62 with the wheels 61 may be a carriage 62A that can be separated or connected from or to the side plate portion 63 having, for example, a cathode unit 68 or anode units 90 attached thereto. In this case, after the electrode unit 31 is connected to the film forming chamber 11, the carriage 62A may be separated from the side plate portion 63 and then used as a common carriage 62A to move the other electrode units 31.

The anode units 90 and the cathode unit 68 which are arranged on both surfaces of the substrate W during a film forming process are provided on one surface (a surface facing the inside of the film forming chamber 11) 65 of the side plate portion 63. The electrode unit 31 according to this embodiment includes the cathode unit 68 and a pair of anode units 90 which are arranged on both sides of the cathode unit 68. One electrode unit 31 can be used to form films on two substrates W at the same time. During the film forming process, the substrates W are arranged on both surfaces of the cathode unit 68 so as to face each other substantially in parallel to the vertical direction. Two anode units 90 are arranged outside each substrate W in the thickness direction so as to face each substrate W.

That is, the cathode unit 68 and the anode units 90 form a parallel-plate-type electrode portion. The anode unit 90 includes a plate-shaped anode 67 and a heater H (for example, a heating wire) provided in the anode 67.

A driving device 71 for driving the anode units 90 and a matching box 72 for supplying power to a cathode intermediate member 76 of the cathode unit 68 during a film forming process are attached to the other surface 69 of the side plate portion 63. In addition, the side plate portion 63 includes a connecting portion (not shown) for a pipe that supplies a film forming gas to the cathode unit 68.

Each of the anode units 90 has the heater H as a temperature control unit that adjusts the temperature of the substrate W. The driving device 71 provided in the side plate portion 63 can move the two anode units 90 in a direction (the horizontal direction) in which the two anode units 90 are away from or close to each other, thereby controlling the distance between the substrate W and the cathode unit 68. Specifically, when a film is formed on the substrate W, the two anode units 90 are moved to the cathode unit 68 and come into contact with each substrate W. In addition, the two anode units 90 are moved in a direction in which they approach the cathode unit 68 and the distance between the substrate W and the cathode unit 68 is adjusted to a desired value. Thereafter, a film is formed on the substrate W, the anode units 90 are moved in a direction in which they are separated from each other after the film is formed, and the anode units 90 are separated from the substrate W. In this way, it is possible to easily take out the substrate W from the electrode unit 31.

The anode unit 90 is attached to the driving device 71 through a hinge (not shown). With the electrode unit 31 taken out from the film forming chamber 11, a surface 67A of the anode unit 90 (anode 67) facing the cathode unit 68 can be pivoted so as to be substantially in parallel to the one surface 65 of the side plate portion 63. That is, the anode unit 90 can be rotated approximately 90° in a plan view (see FIG. 4A).

The cathode unit 68 includes a pair of shower plates (cathodes) 75, the cathode intermediate member 76, a discharge duct 79, an insulating member 82, and a feeding point 88.

A plurality of small holes (not shown) is formed in the surfaces of the pair of shower plates facing the anode units 90 (anodes 67) and a film forming gas is discharged from the small holes to the substrate W. The shower plates 75, 75 are electrically connected to the matching box 72 to form the cathodes (radio frequency electrodes). The cathode intermediate member 76 that is electrically connected to the matching box 72 is provided between the pair of shower plates 75, 75. That is, the shower plates 75 are provided on both surfaces of the cathode intermediate member 76 so as to be electrically connected to the cathode intermediate member 76.

The cathode intermediate member 76 and the shower plates (cathodes) 75 are made of a conductor. A voltage is applied from the radio frequency power supply to the shower plates (cathodes) 75 through the cathode intermediate member 76. That is, the voltages applied to the two shower plates 75, 75 in order to generate plasma have the same potential and phase.

As shown in FIG. 4D, the cathode intermediate member 76 is a flat plate. The cathode intermediate member 76 is electrically connected to the radio frequency power supply (not shown) through the matching box 72. The matching box 72 matches the cathode intermediate member 76 with the radio frequency power supply. One matching box 72 is provided on the other surface 69 of the side plate portion 63 of the electrode unit 31. The feeding point 88 to which a voltage is applied from the radio frequency power supply through the matching box 72 is provided in the cathode intermediate member 76. Wiring lines are provided between the feeding point 88 and the matching box 72.

The wiring lines extend from the matching box 72 to the feeding point 88 along the outer circumference of the cathode intermediate member 76. The outer circumference of the cathode intermediate member 76, the feeding point 88, and the wiring lines are surrounded by the insulating member 82 made of, for example, alumina or silica.

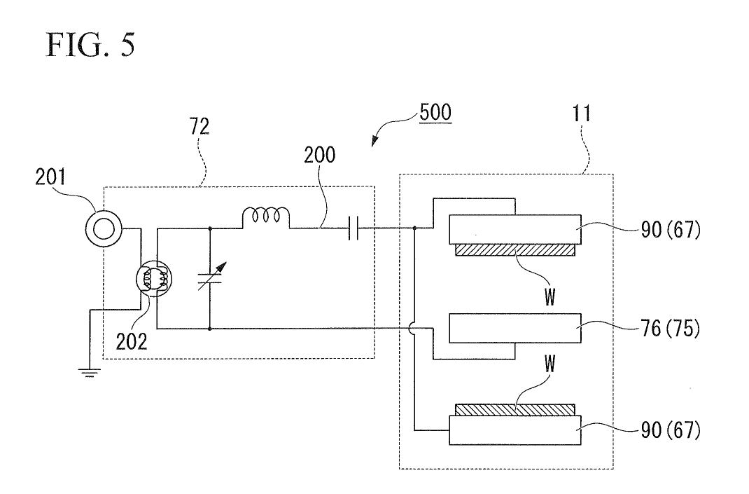

FIG. 5 is a circuit diagram illustrating one electrode unit 31. That is, FIG. 5 is a circuit diagram illustrating an electrode circuit 500 according to an embodiment of the present invention. As shown in FIG. 5, in the electrode circuit 500 according to this embodiment, an RF power supply (radio frequency power supply) 201 and the cathode intermediate member 76 are electrically connected to each other through the matching box 72. The electrode circuit 500 includes the RF power supply 201; a matching circuit 200 in the matching box 72; the cathode intermediate member 76; the anode units 90; and plasma generated between the cathode intermediate member 76 and the anode units 90. The electrode circuit 500 is a balanced circuit. Specifically, the RF power supply 201 and the matching circuit 200 are electrically connected to each other through an insulating transformer 202 provided in the matching box 72. One end of the matching circuit 200 is electrically connected to the cathode intermediate member 76 and the other end thereof is electrically connected to the anode units 90 (anodes 67). In the electrode circuit 500 according to this embodiment, the anodes 67 are provided on both sides of the cathode intermediate member 76. The electrode surfaces of the anodes 67 face each other, one surface of the cathode intermediate member 76 faces one of the anodes 67, and the other surface of the cathode intermediate member 76 faces the other anode 67. Therefore, the other end of the matching circuit 200 is branched and electrically connected to the two anodes 67. The connection of the matching circuit 200, the cathode intermediate member 76, and the anodes 67 may be reversed.

As such, since the electrode circuit 500 including the RF power supply 201; the matching circuit 200; the cathode intermediate member 76; the anode units 90; and the plasma generated between the cathode intermediate member 76 and the anode units 90 is a balanced circuit, a current flows only between the cathode intermediate member 76 and the anodes 67 during deposition in the film forming chamber 11. Therefore, plasma is generated only between the cathode intermediate member 76 and the anodes 67. Therefore, uniform plasma is generated between the cathode intermediate member 76 and the anodes 67. As a result, it is possible to form a uniform film on a film forming surface WO of the substrate W.

According to the structure in which the electrode circuit 500 is a balanced circuit, even when one of the plurality of electrode units 31 provided in the film forming chamber 11 is not operated due to, for example, a defect, uniform plasma is generated between the cathode intermediate members 76 and the anodes 67 of the other electrode units 31 without being affected by the failure. Therefore, when films are formed on a plurality of substrates W in the film forming chamber 11 at the same time, it is possible to form uniform films on the film forming surfaces WO of all of the substrates W.

In addition, according to the structure in which the electrode circuit 500 is a balanced circuit, a current flows only between the cathode intermediate member 76 and the anode 67 and no current theoretically flows between the cathode intermediate member 76 and the inner wall of the film forming chamber 11. Therefore, no discharge occurs at that position. Therefore, it is possible to prevent a film from being formed on the inner wall of the film forming chamber 11. As a result, it is possible to prevent the generation of particles.

It is possible to generate plasma between the cathode unit 68 and the two anodes 67 (anode units 90) provided on both sides of the cathode unit 68 by applying a voltage to the cathode unit 68 (cathode intermediate member 76). That is, it is possible to simultaneously form films on two substrates W with one cathode unit 68.

Next, electrode waveforms when the electrode circuit 500 is a balanced circuit as described above will be described.

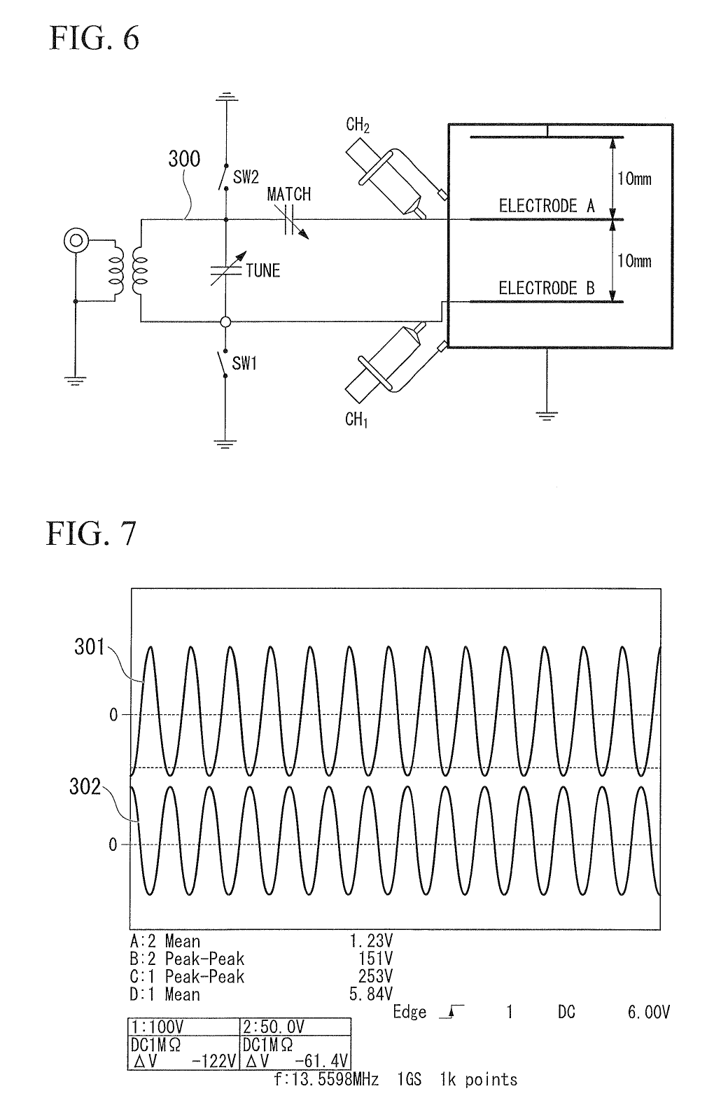

FIG. 7 shows the waveforms of voltages of electrodes A and B when a balanced circuit 300 shown in FIG. 6 is used.

As shown in FIG. 7, a phase difference between the waveform 301 of the potential of the electrode A and the waveform 302 of the potential of the electrode B is 180°. When the waveforms of the potentials of the electrodes A and B are combined with each other, few

DC voltage components (VDC voltage components) are generated. That is, in the thin-film solar cell manufacturing apparatus according to this embodiment, the flowing of current between the cathode intermediate member 76 and the inner wall of the film forming chamber 11 is prevented and most of the current flows between the cathode intermediate member 76 and the anode units 90 (anodes 67). Therefore, plasma is generated only between the cathode intermediate member 76 and the anode units 90. As a result, it is possible to form a uniform film on the substrate W, as described above.

As shown in FIG. 5, the insulating transformer 202 is provided between the RF power supply 201 and the matching circuit 200. Therefore, in the electrode circuit 500 according to this embodiment, impedance is more than that when the insulating transformer 202 is provided between the matching circuit 200 and the cathode intermediate member 76 and the voltage and current have the same phase. As a result, it is possible to reduce the size of the insulating transformer 202.

As shown in FIG. 4D, a space 77 is formed between the cathode intermediate member 76 and each shower plate 75. The film forming gas is introduced from a gas supply apparatus (not shown) to the space 77. The spaces 77 are separated from each other by the cathode intermediate member 76 interposed therebetween and are individually formed so as to correspond to the shower plates 75, 75. Therefore, it is possible to individually control the kind or amount of gas emitted from each of the shower plates 75, 75. That is, the space 77 serves as a gas supply path. In this embodiment, since the spaces 77 are individually formed so as to correspond to the shower plates 75, 75, the cathode unit 68 includes two gas supply paths.

The hollow discharge duct 79 is provided substantially at the entire edge of the cathode unit 68. Vacuuming ports 80 for introducing and exhausting the film forming gas or a reaction product (powder) in the film formation space 81 to the discharge duct 79 are formed in the discharge duct 79. Specifically, when a film is formed, the vacuuming ports 80 are formed so as to face the film formation space 81 that is formed between the substrate W and the shower plate 75. A plurality of vacuuming ports 80 is formed along the edge of the cathode unit 68 so that a gas can be substantially uniformly exhausted along the entire edge.

An opening α (not shown) is formed in a surface 83 facing the film forming chamber 11 in the discharge duct 79 that is provided at a lower part of the cathode unit 68. For example, the film forming gas exhausted from the film formation space 81 is discharged into the film forming chamber 11 through the opening α. The gas discharged into the film forming chamber 11 is exhausted to the outside through an vacuuming pipe 29 that is provided in the lower portion 28 of the lateral surface of the film forming chamber 11 (see FIG. 3C).

A dielectric and/or the insulating member 82 having a space for laminating the dielectric is provided between the discharge duct 79 and the cathode intermediate member 76. The discharge duct 79 is connected to the ground potential. The discharge duct 79 also functions as a shield frame for preventing an abnormal discharge from the cathode 75 and the cathode intermediate member 76.

A mask 78 is provided at the edge of the cathode unit 68 so as to cover a portion from the outer circumference of the discharge duct 79 to the outer circumference of each shower plate (cathode) 75.

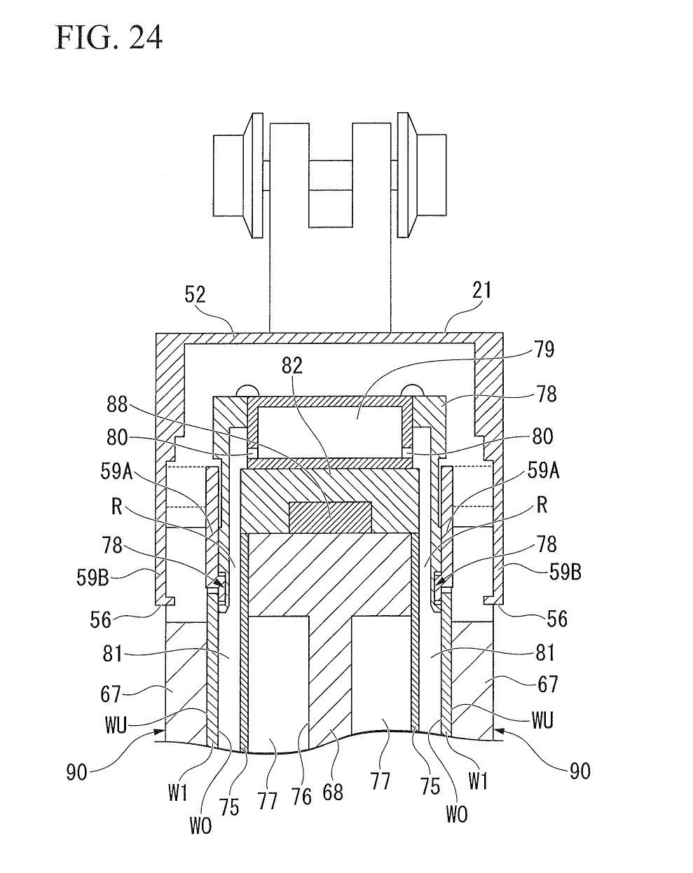

The masks 78 cover holding pieces 59A (see FIGS. 12 and 24) of a holding portion 59 (which will be described below) provided in the carrier 21 and are integrated with the holding pieces 59A to form a gas flow path R for introducing the film forming gas or the reaction product (powder) in the film formation space 81 to the discharge duct 79 when a film is formed. That is, the gas flow path R is formed between the carrier 21 (holding piece 59A) and the shower plate 75 and between the carrier 21 (holding piece 59A) and the discharge duct 79. The masks 78 may be electrically connected to the ground.

When the electrode unit 31 is provided, two spaces into which the substrates W are inserted are formed between the anode units 90 and the cathode unit 68 by one electrode unit 31. Therefore, it is possible to simultaneously form films on two substrates W with one electrode unit 31.

In general, when a thin Si layer is formed on a substrate by a plasma CVD method, the gap between the substrate and the cathode unit needs to be set in the range of approximately 5 mm to 15 mm. Therefore, when the substrate is carried in and out, the substrate is likely to contact the anode unit or the cathode unit and to be damaged. In contrast, in the thin-film solar cell manufacturing apparatus according to this embodiment, the substrate W is arranged between the anode unit 90 and the cathode unit 68, and the anode unit 90 (anode 67) comes into contact with the substrate W and can be moved in order to adjust the distance between the substrate W and the cathode unit 68. Therefore, it is possible to adjust the distance between the anode 67 and the cathode unit 68 before and after a film is formed. As a result, it is possible to carry in and out the substrate W easier than ever before. When the substrate W is carried in and out, it is possible to prevent the substrate W from being damaged due to a contact with the anode 67 or the cathode unit 68.

In general, when a film is formed on the substrate, the formation of the film is performed while the substrate is heated. In the film formation device according to this embodiment, since the anode 67 (anode unit 90) having the heater H provided therein comes into contact with the substrate W, it is possible to effectively transfer heat generated from the heater H to the substrate W. Therefore, it is possible to form a high-quality film on the substrate W.

The cathode unit 68 and the anode units 90 of the electrode unit 31 need to be periodically maintained in order to remove the deposited film. Since the electrode unit 31 according to this embodiment is removable from the film forming chamber 11, it is easy to maintain the cathode unit 68 and the anode units 90. When a spare electrode unit 31 is prepared, the electrode unit 31 is removed from the film forming chamber 11 and is replaced with the spare electrode unit 31 during maintenance. In this way, maintenance is performed without stopping the manufacturing line. Therefore, it is possible to improve production efficiency. As a result, even when a semiconductor layer is formed on the substrate W at a low rate, it is possible to manufacture the semiconductor layer with high throughput.

As shown in FIG. 2, a plurality of transfer rails 37 is installed between the film forming chamber 11 and the substrate replacement chamber 15 such that the carrier 21 can be moved between the film forming chamber 11 and the loading-ejecting chamber 13 and between the loading-ejecting chamber 13 and the substrate replacement chamber 15. The transfer rails 37 are separated between the film forming chamber 11 and the loading-ejecting chamber 13 and the shutter 25 is closed to airtightly seal the carrier transfer inlet port 24.

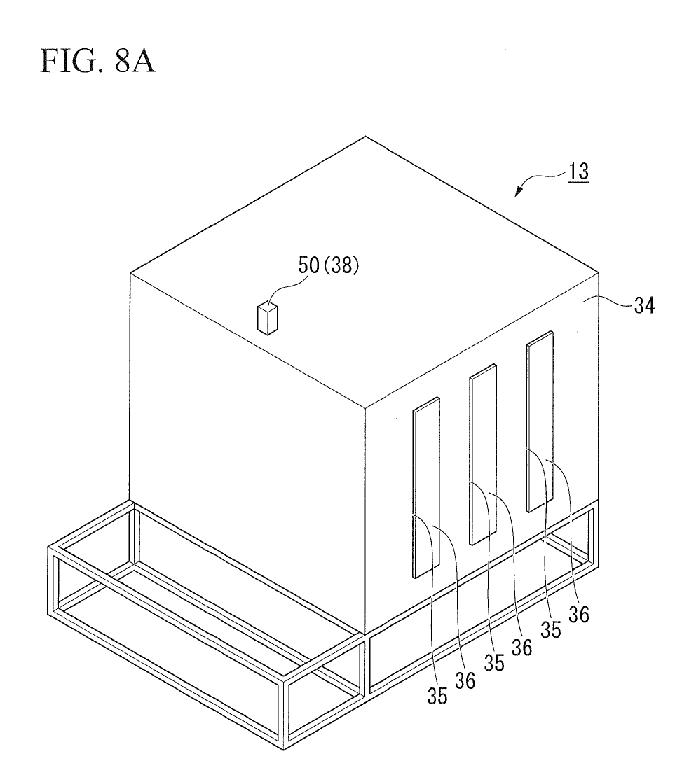

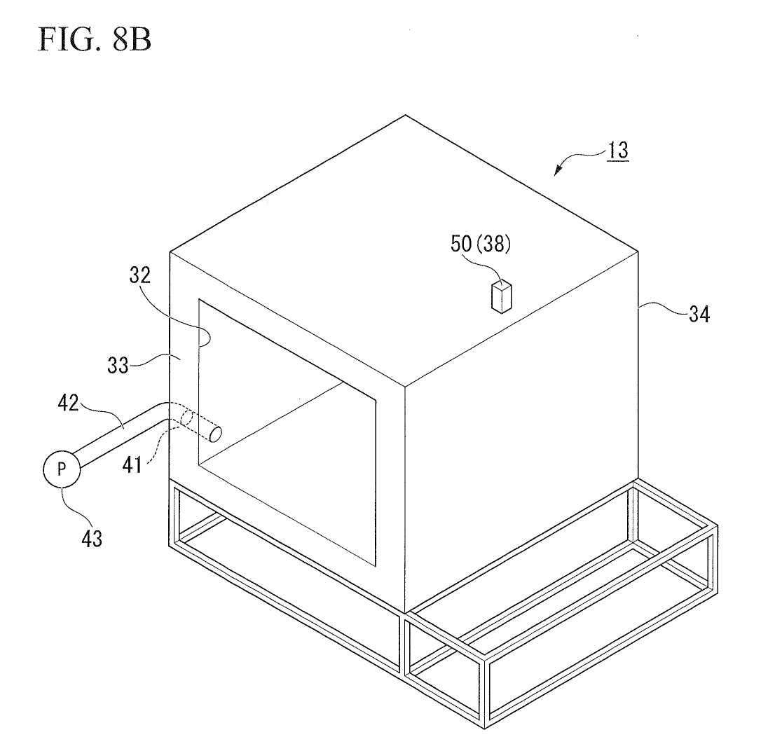

FIGS. 8A and 8B are perspective views schematically illustrating the loading-ejecting chamber 13. FIG. 8A is a perspective view and FIG. 8B is a perspective view illustrating the loading-ejecting chamber 13, as viewed from an angle different from that in FIG. 8A. As shown in FIGS. 8A and 8B, the loading-ejecting chamber 13 has a box shape. A first lateral surface 33 of the loading-ejecting chamber 13 is connected to the first lateral surface 23 of the film forming chamber 11 such that airtightness is ensured therebetween. Openings 32 through which three carriers 21 can pass are formed in the first lateral surface 33. A second lateral surface 34 opposite to the first lateral surface 33 is connected to the substrate replacement chamber 15. Three carrier transfer inlet ports 35 through which the carriers 21 having the substrates W loaded thereon can pass are formed in the second lateral surface 34. Shutters 36 capable of ensuring airtightness are provided in the carrier transfer inlet ports 35. Each transfer rail 37 is separated between the loading-ejecting chamber 13 and the substrate replacement chamber 15. The shutter 36 is closed to airtightly seal the carrier transfer inlet port 35.

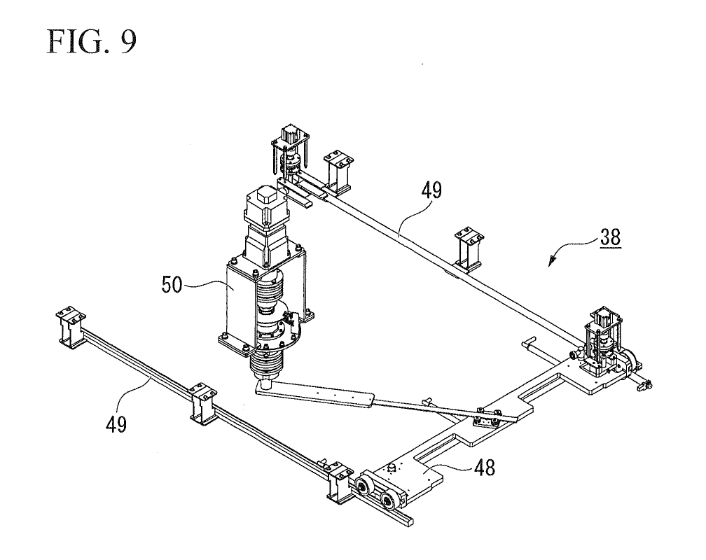

A push-pull mechanism 38 is provided in the loading-ejecting chamber 13 in order to move the carrier 21 between the film forming chamber 11 and the loading-ejecting chamber 13 along the transfer rail 37. As shown in FIG. 9, the push-pull mechanism 38 includes a locking portion 48 that locks the carrier 21; a pair of guide members 49 that is provided at both ends of the locking portion 48 substantially in parallel to the transfer rail 37; and a moving device 50 that moves the locking portion 48 along the guide members 49.

A moving mechanism (not shown) for storing the pre-processed substrate W1 and the post-processed substrate W2 at the same time is provided in the loading-ejecting chamber 13. The moving mechanism moves the carrier 21 by a predetermined distance in a direction substantially orthogonal to the direction in which the transfer rail 37 is installed in a plan view.

A vacuum pump 43 for evacuating the loading-ejecting chamber 13 is connected to a lower portion 41 of a third lateral surface of the loading-ejecting chamber 13 through an vacuuming pipe 42 (see FIG. 8B).

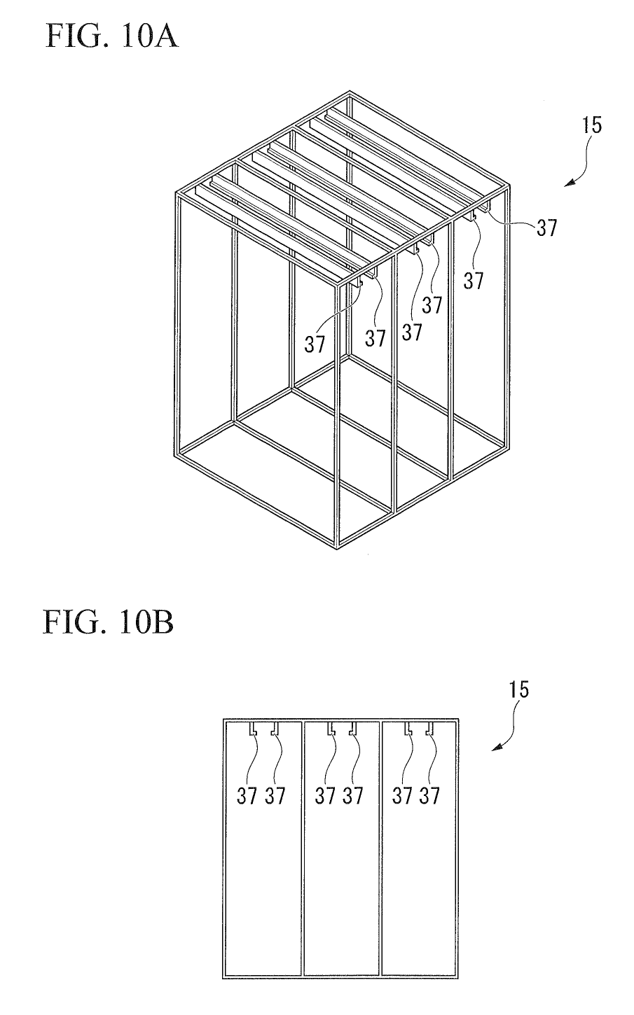

FIGS. 10A and 10B are diagrams schematically illustrating the structure of the substrate replacement chamber 15. FIG. 10A is a perspective view illustrating the substrate replacement chamber 15 and FIG. 10B is a front view illustrating the substrate replacement chamber 15. As shown in FIGS. 10A and 10B, the substrate replacement chamber 15 has a frame shape and is connected to the second lateral surface 34 of the loading-ejecting chamber 13. In the substrate replacement chamber 15, the pre-processed substrate W1 is attached to the carrier 21 arranged on the transfer rail 37 and the post-processed substrate W2 is detached from the carrier 21. Three carriers 21 can be arranged in parallel in the substrate replacement chamber 15.

The substrate replacement robot 17 has a driving arm 45 (see FIG. 2). The driving arm 45 absorbs the substrate W with its leading end. The driving arm 45 is driven between the carrier 21 provided in the substrate replacement chamber 15 and the substrate storage holder 19. The driving arm 45 takes out the pre-processed substrate W1 from the substrate storage holder 19 and attaches the pre-processed substrate W1 to the carrier 21 provided in the substrate replacement chamber 15. The driving arm 45 detaches the post-processed substrate W2 from the carrier 21 returned to the substrate replacement chamber 15 and transports the post-processed substrate W2 to the substrate storage holder 19.

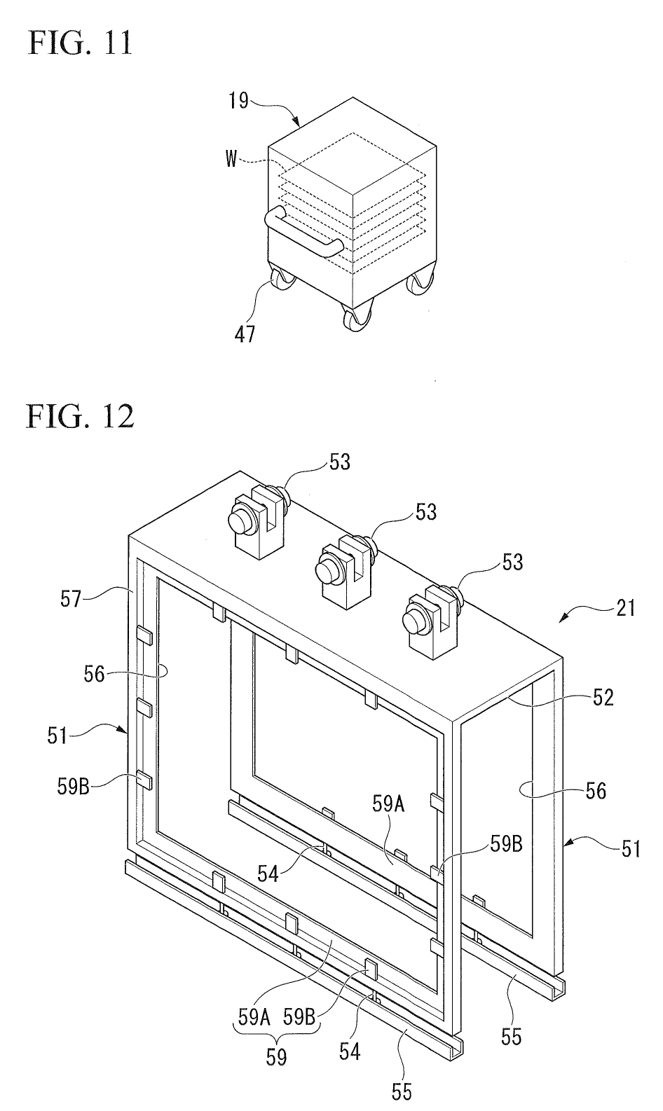

FIG. 11 is a perspective view illustrating the substrate storage holder 19. As shown in FIG. 11, the substrate storage holder 19 is formed in a box shape and has a size capable of storing a plurality of substrates W. The substrate storage holder 19 stores a plurality of substrates W laminated in the vertical direction with the film forming surfaces of the substrates W arranged in the horizontal direction. Casters 47 are provided at four corners of the bottom of the substrate storage holder 19 such that the substrate storage holder 19 can be easily moved to another processing apparatus.

FIG. 12 is a perspective view illustrating the carrier 21 that transports the substrate W. As shown in FIG. 12, the carrier 21 includes two frames 51 to which the substrates W can be attached. That is, two substrates W are attached to one carrier 21. The upper parts of the two frames 51, 51 are connected by a connecting member 52 and the two frames 51, 51 are integrated with each other. A plurality of wheels 53 that is loaded on the transfer rails 37 is provided on the upper surface of the connecting member 52. The wheels 53 are rotated on the transfer rails 37 such that the carrier 21 can be moved along the transfer rails 37. A frame holder 54 that prevents the rocking of the substrate W when the carrier 21 is moved is provided at a lower part of the frame 51. The lower end of the frame holder 54 is fitted to a rail member 55 that has a V-shape in a cross-sectional view and is provided on the bottom of each chamber. The rail member 55 is arranged along the transfer rail 37 in a plan view. When the frame holder 54 includes a plurality of rollers, it is possible to further improve the stability of transport.

Each of the frames 51 includes an edge portion 57 and a holding portion 59. The film forming surface of the substrate W is exposed through the opening 56 formed in the frame 51. The substrate W is interposed between both sides of the holding portion 59 and is fixed at the edge portion 57 of the opening 56.

The urging force of a spring is applied to the holding portion 59 for holding the substrate W. The holding portion 59 includes the holding pieces 59A and 59B that come into contact with the front surface WO (film forming surface) and the rear surface WU (rear surface) of the substrate W (see FIG. 24). The distance between the holding piece 59A and the holding piece 59B can be changed by, for example, the spring. That is, the distance can be changed in a direction in which the holding piece 59A is close to or away from the holding piece 59B, depending on the movement of the anode 67 (which will be described in detail below). In each chamber, one carrier 21 (one carrier 21 capable of holding a pair of (two) substrates W) is attached onto one transfer rail 37. That is, three carriers 21 are attached to one substrate film formation line 16 including the film forming chamber 11, the loading-ejecting chamber 13, and the substrate replacement chamber 15 (three pairs of six substrates are held).

In the thin-film solar cell manufacturing apparatus 10 according to this embodiment, four substrate film formation lines 16 are arranged and three carriers 21 are provided in one film forming chamber 11. Therefore, it is possible to form films on 24 substrates W substantially at the same time.

### (Method of Manufacturing Thin-Film Solar Cell)

Next, a film formation method according to an embodiment of the present invention will be described. In the film formation method according to this embodiment, the thin-film solar cell manufacturing apparatus 10 is used to form a film on the substrate W. In the description, the drawings of one substrate film formation line 16 are used. However, the other three substrate film formation lines 16 form films on the substrates W along substantially the same flow.

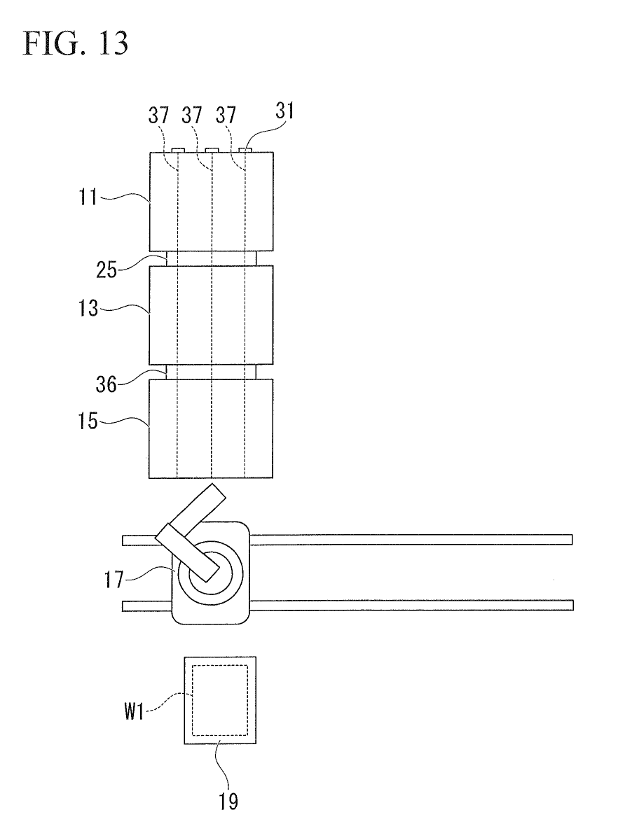

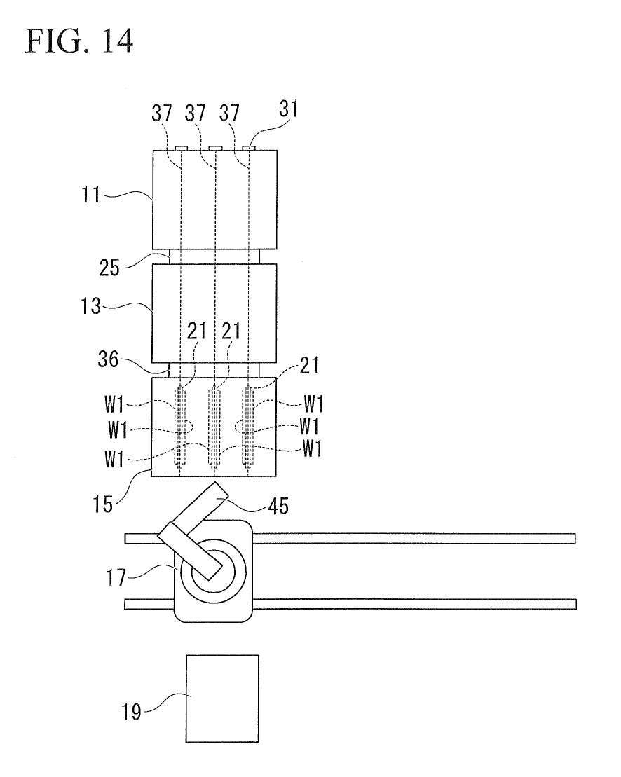

First, as shown in FIG. 13, the substrate storage holder 19 having a plurality of pre-processed substrates W1 stored therein is disposed at a predetermined position.

Then, as shown in FIG. 14, the driving arm 45 of the substrate replacement robot 17 is operated to take out one pre-processed substrate W1 from the substrate storage holder 19 and attach the pre-processed substrate W1 to the carrier 21 in the substrate replacement chamber 15. At that time, the pre-processed substrate W1 which is arranged in the substrate storage holder 19 in the horizontal direction is vertically attached to the carrier 21. This operation is repeated one more time to attach two pre-processed substrates W1 to one carrier 21. This operation is repeated to attach the pre-processed substrates W1 to the other two carriers 21 in the substrate replacement chamber 15. That is, in this stage, six pre-processed substrates W1 are attached.

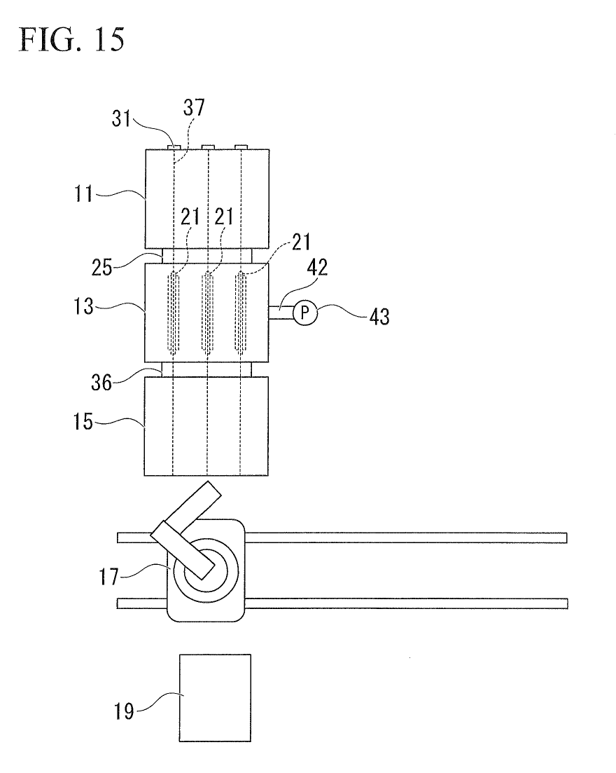

Then, as shown in FIG. 15, three carriers 21 having the pre-processed substrates W1 attached thereto are moved into the loading-ejecting chamber 13 along the transfer rails 37 substantially at the same time. After the carriers 21 are moved into the loading-ejecting chamber 13, the shutters 36 of the carrier transfer inlet ports 35 of the loading-ejecting chamber 13 are closed. Then, the inside of the loading-ejecting chamber 13 is maintained in a vacuum state by the vacuum pump 43.

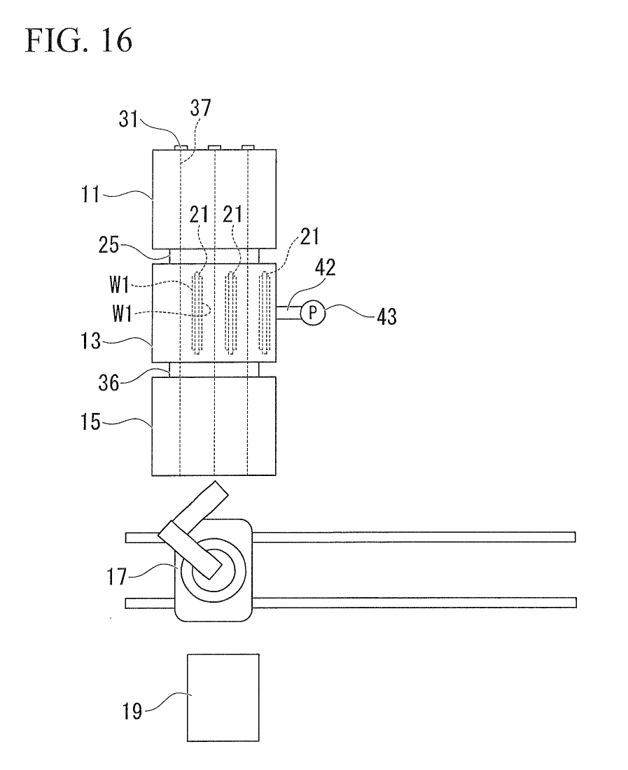

Then, as shown in FIG. 16, the three carriers 21 are moved a predetermined distance (half pitch) by the moving mechanism in a direction orthogonal to the direction in which each transfer rail 37 is installed in a plan view. The predetermined distance means a distance from the transfer rail 37 having one carrier 21 placed thereon to the position of the carrier 21 between the transfer rail 37 and an adjacent transfer rail 37.

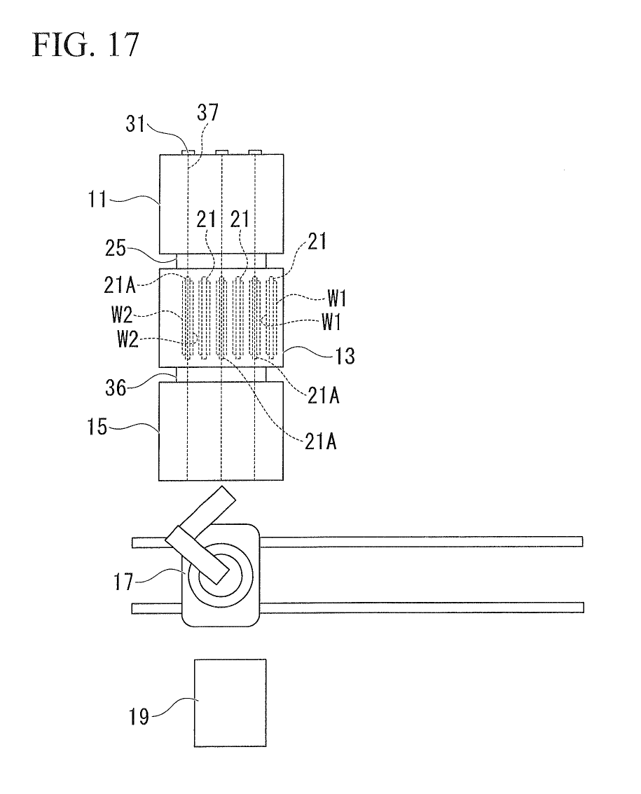

Then, as shown in FIG. 17, the shutters 25 of the film forming chamber 11 are opened and the carriers 21A to which the post-processed substrates W2 having films formed thereon in the film forming chamber 11 are attached are moved to the loading-ejecting chamber 13 by the push-pull mechanism 38. At that time, the carriers 21 holding the pre-processed substrates W1 and the carriers 21A holding the post-processed substrates W2 are alternately arranged in parallel in a plan view. This state is maintained for a predetermined period of time, and heat stored in the post-processed substrate W2 is transferred to the pre-processed substrate W 1. That is, the pre-processed substrate W1 is heated.

Next, the operation of the push-pull mechanism 38 will be described. The operation of the push-pull mechanism 38 when the push-pull mechanism 38 moves the carrier 21A in the film forming chamber 11 to the loading-ejecting chamber 13 will be described.

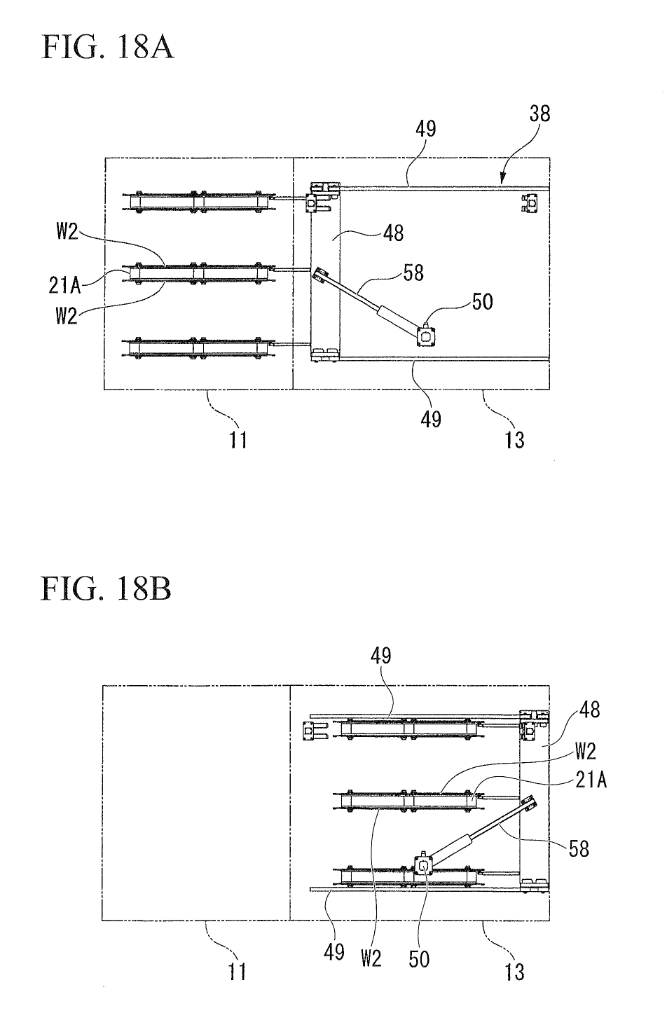

As shown in FIG. 18A, the locking portion 48 of the push-pull mechanism 38 locks the carrier 21A having the post-processed substrates W2 attached thereto. Then, a moving arm 58 of the moving device 50 attached to the locking portion 48 is tilted. At that time, the length of the moving arm 58 is variable. Then, the locking portion 48 locking the carrier 21A is moved while being guided by the guide members 49. As shown in FIG. 18B, the carrier 21A is moved from the film forming chamber 11 to the loading-ejecting chamber 13. This structure makes it unnecessary to provide a driving source for driving the carrier 21A in the film forming chamber 11.

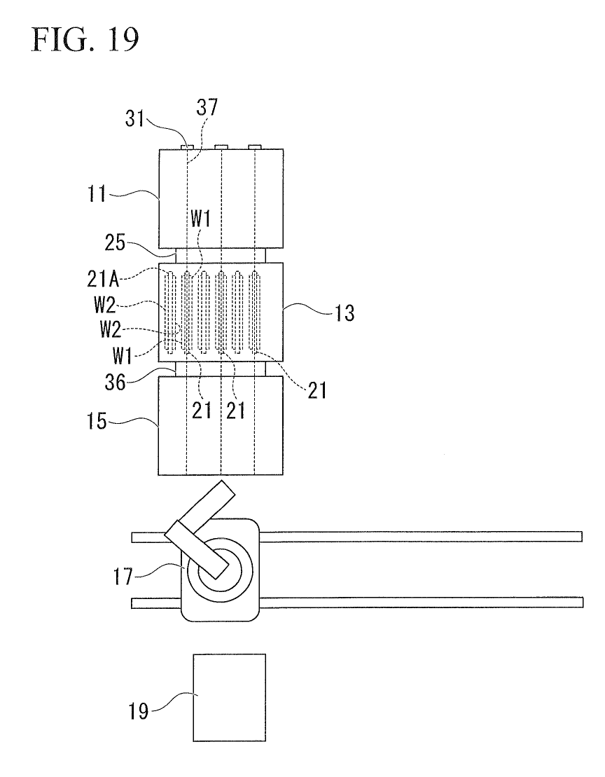

Then, as shown in FIG. 19, the carriers 21 and the carriers 21A are moved by the moving mechanism in a direction perpendicular to the transfer rail 37 and the carriers 21 holding the pre-processed substrates W1 are moved to the positions of the transfer rails 37.

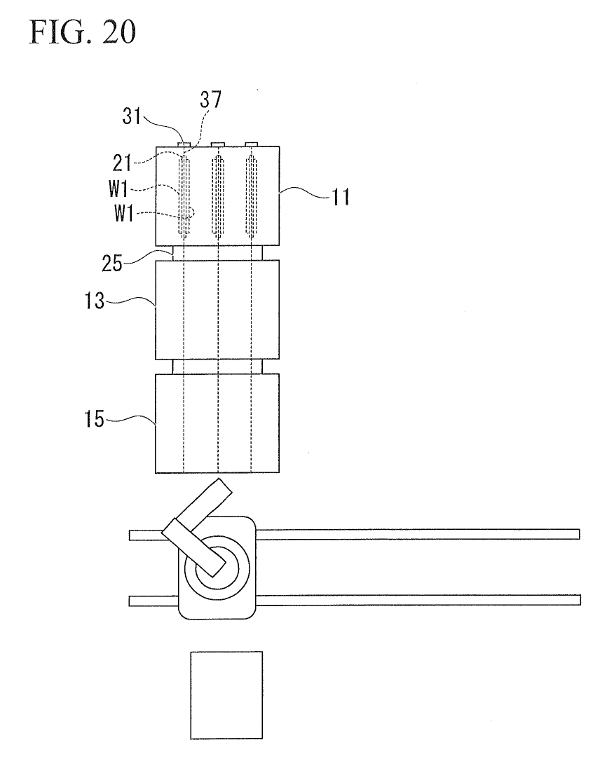

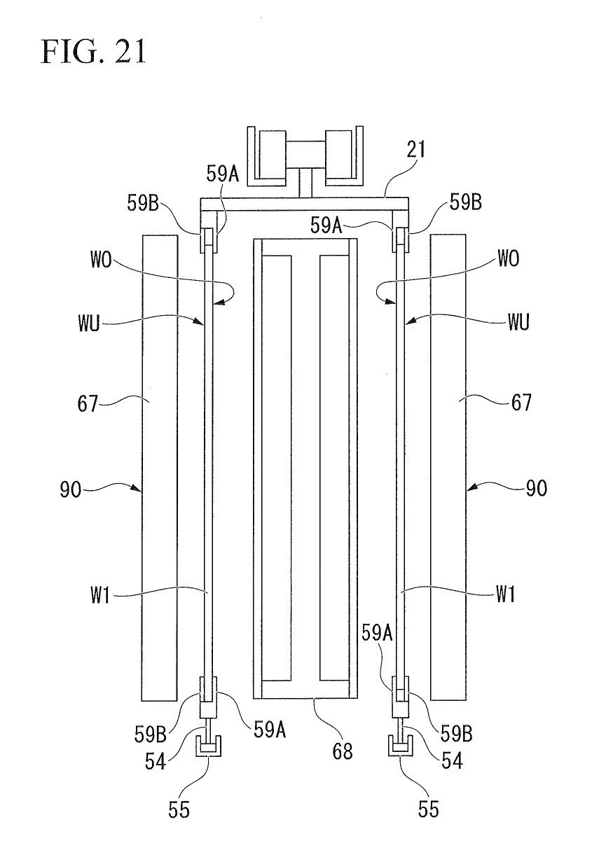

Then, as shown in FIG. 20, the push-pull mechanism 38 is used to move the carriers 21 holding the pre-processed substrates W1 to the film forming chamber 11 and the shutters 25 are closed after the carriers 21 are moved to the film forming chamber 11. The film forming chamber 11 is maintained in a vacuum state. At that time, each of the pre-processed substrates W1 attached to the carriers 21 is moved along the planar direction thereof, and the pre-processed substrate W1 is inserted between the anode unit 90 and the cathode unit 68 such that the front surface WO thereof is substantially in parallel to the vertical direction in the film forming chamber 11 (see FIG. 21).

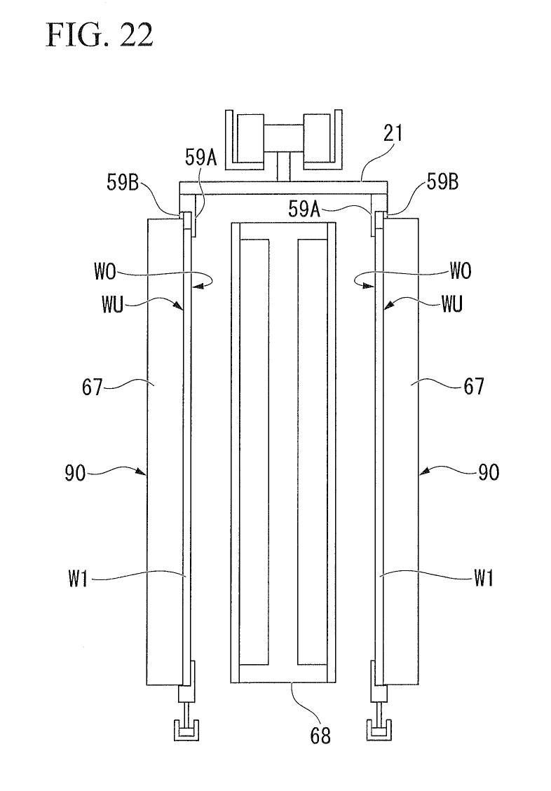

Then, as shown in FIGS. 21 and 22, two anode units 90 of the electrode unit 31 are moved by the driving device 71 in a direction in which they are close to each other and the anode units 90 (anodes 67) come into contact with the rear surfaces WU of the pre-processed substrates W1.

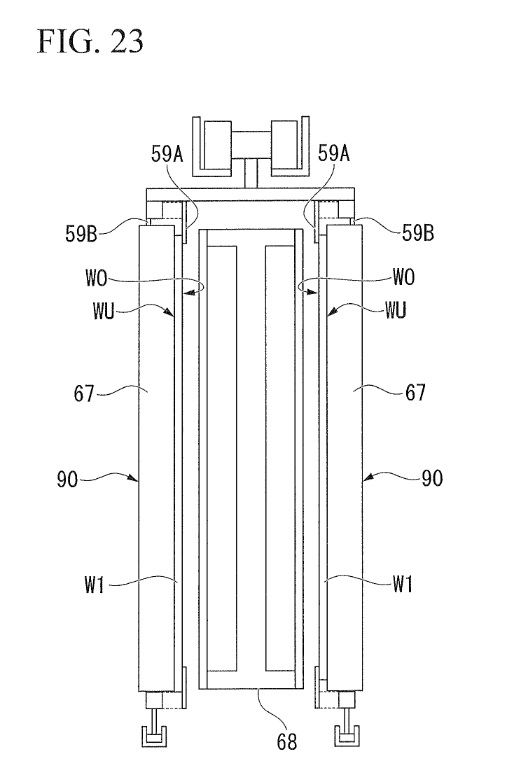

As shown in FIG. 23, when the driving device 71 is further driven, the pre-processed substrate W1 is moved to the cathode unit 68 so as to be pressed against the anode 67. Then, the pre-processed substrate W1 is moved until the gap between the pre-processed substrate W1 and the shower plate 75 of the cathode unit 68 becomes a predetermined distance (film forming distance). The gap (film forming distance) between the pre-processed substrate W1 and the shower plate 75 of the cathode unit 68 is in the range of 5 mm to 15 mm. For example, the gap may be approximately 5 mm.

The holding piece 59A of the holding portion 59 of the carrier 21 that comes into contact with the front surface WO of the pre-processed substrate W1 is displaced in a direction in which it is separated from the holding piece 59B with the movement (the movement of the anode unit 90) of the pre-processed substrate W1. When the anode unit 90 is moved in a direction in which it is separated from the cathode unit 68, for example, the restoring force of a spring (not shown) is applied to the holding piece 59A. Therefore, the holding piece 59A is displaced to the holding piece 59B. In this case, the pre-processed substrate W1 is interposed between the anode 67 and the holding piece 59A.

When the pre-processed substrate W1 is moved to the cathode unit 68, the holding piece 59A comes into contact with the mask 78. At that time, the movement of the anode unit 90 stops (see FIG. 24).

As shown in FIG. 24, the mask 78 is formed so as to cover the front surface of the holding piece 59A and the edge of the substrate W and come into close contact with the holding piece 59A or the edge of the substrate W. That is, the contact surface between the mask 78 and the holding piece 59A or the edge of the substrate W serves as a sealing surface and little film forming gas leaks between the mask 78 and the holding piece 59A or the edge of the substrate W to the anode 67. In this way, the diffusion range of the film forming gas is limited and it is possible to prevent a film from being formed in an unnecessary range. As a result, it is possible to narrow the cleaning range and reduce the number of times cleaning is performed. Therefore, the operation rate of the thin-film solar cell apparatus 10 is improved.

The movement of the pre-processed substrate W1 stops when the holding piece 59A or the edge of the substrate W comes into contact with the mask 78. Therefore, the gap between the mask 78 and the shower plate 75 and the gap between the mask 78 and the discharge duct 79, that is, the dimensions of the gas flow path R in the thickness direction are set such that the gap between the pre-processed substrate W1 and the cathode unit 68 is a predetermined distance.

As another aspect, the mask 78 may be attached to the discharge duct 79 with an elastic body interposed therebetween. In this case, the distance between the substrate and the shower plate (cathode) 75 can be optionally changed by a stroke of the driving device 71. In this embodiment, the mask 78 comes into contact with the substrate W. However, the mask 78 and the substrate W may be arranged such that a very small gap for limiting the flow of the film forming gas is formed therebetween.

Then, the film forming gas is ejected from the shower plate 75 of the cathode unit 68 and the matching box 72 starts up to apply a voltage from the radio frequency power supply to the shower plate (cathode) 75 through the matching box 72 and the cathode intermediate member 76 of the cathode unit 68. In this way, plasma is generated in the film formation space 81 and a film is formed on the front surface WO of the pre-processed substrate W1. At that time, the heater H provided in the anode 67 heats the pre-processed substrate W1 at a desired temperature.

The anode unit 90 stops heating when the substrate W1 reaches the desired temperature before a film forming process. However, when a voltage is applied to the shower plate (cathode) 75 and plasma is generated in the film formation space 81, there is a concern that the temperature of the pre-processed substrate W1 will be higher than the desired temperature due to heat input from the plasma over time even though the anode unit 90 stops heating. In this case, the anode unit 90 can function as a radiator plate for cooling the pre-processed substrate W1 whose temperature has increased. Therefore, the temperature of the pre-processed substrate W1 is adjusted to a desired temperature regardless of the elapse of the processing time during a film forming process.

When a plurality of layers is formed by one film forming process, it is possible to switch film forming gas materials that are supplied at a predetermined time interval.

During the formation of a film and after a film is formed, the gas or reaction product (particle) in the film formation space 81 flows into the discharge duct 79 through the gas flow path R and the vacuuming port 80 formed at the edge of the cathode unit 68. Of the gas and the reaction product, the gas flowing into the discharge duct 79 passes through the opening a of the discharge duct 79 provided at a lower part of the cathode unit 68 and is exhausted from the vacuuming pipe 29 provided in the lower portion 28 of the lateral surface of the film forming chamber 11 to the outside.

The reaction product (particle) generated when a film is formed is attracted to the inner wall of the discharge duct 79. In this way, it is possible to collect and dispose of the reaction product.

All of the electrode units 31 in the film forming chamber 11 perform the same process as described above. Therefore, it is possible to form films on all of six substrates at the same time.

After the film forming process ends, the driving device 71 moves the two anode units 90 in a direction in which the two anode units 90 are separated from each other and the post-processed substrate W2 and the frame 51 (holding piece 59A) return to the original positions (see FIG. 22). When the anode units 90 are moved in the direction in which the anode units 90 are separated from each other, the post-processed substrates W2 are separated from the anode units 90 (see FIG. 21).

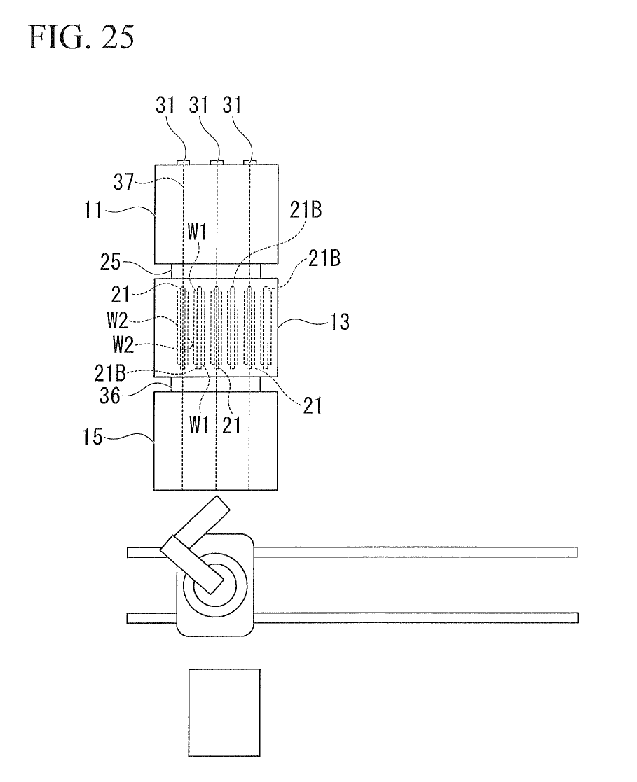

Then, as shown in FIG. 25, the shutters 25 of the film forming chamber 11 are opened and each carrier 21 is moved into the loading-ejecting chamber 13 by the push-pull mechanism 38. At that time, the loading-ejecting chamber 13 is evacuated and the carriers 21B to which the next pre-processed substrates W1 on which films will be formed are attached are arranged in the loading-ejecting chamber 13. Then, the heat stored in the post-processed substrates W2 in the loading-ejecting chamber 13 is transferred to the pre-processed substrates W1 and the temperature of the post-processed substrates W2 is reduced.

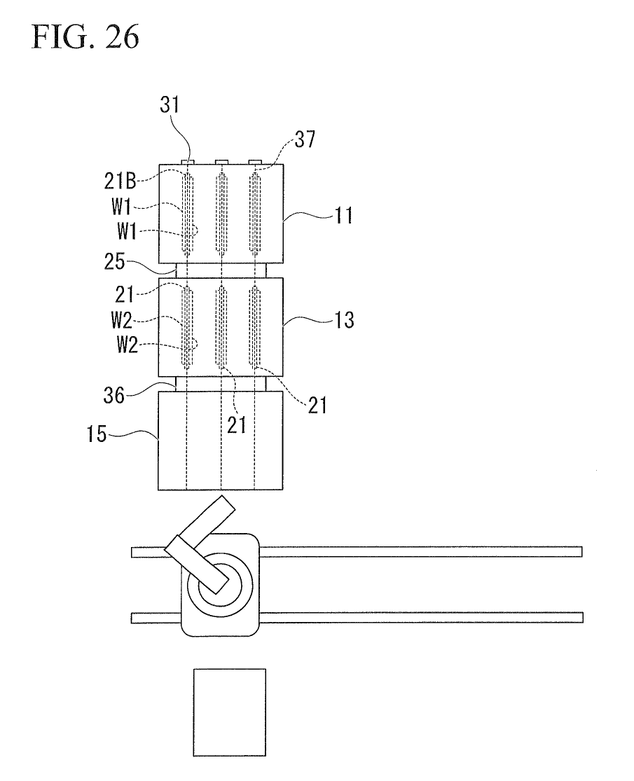

Then, as shown in FIG. 26, each carrier 21B is moved into the film forming chamber 11 and the moving mechanism returns each carrier 21 to the positions of the transfer rails 37.

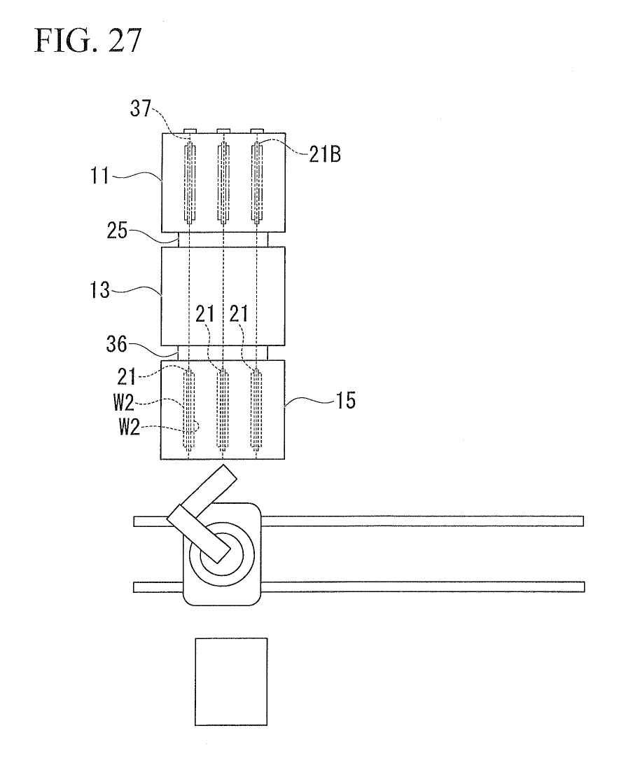

Then, as shown in FIG. 27, after the shutters 25 are closed, the internal pressure of the loading-ejecting chamber 13 is changed to atmospheric pressure and the temperature of the post-processed substrate W2 is reduced to a predetermined temperature. Then, the shutters 36 are opened and each carrier 21 is moved into the substrate replacement chamber 15.

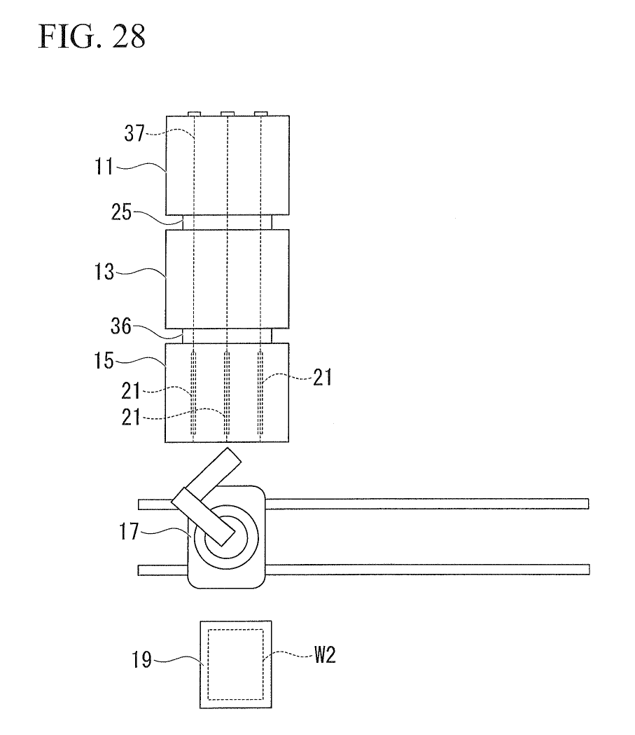

Then, as shown in FIG. 28, the post-processed substrates W2 are detached from the carriers 21 by the substrate replacement robot 17 in the substrate replacement chamber 15 and then moved to the substrate storage holder 19. When the detachment of all of the post-processed substrates W2 is completed, the substrate storage holder 19 is moved to a position for the next process. In this way, the film forming process ends.

According to this embodiment, the electrode circuit 500 applying a voltage to the cathode intermediate member 76 is a balanced circuit. Therefore, when a voltage is applied to the cathode intermediate member 76 (cathode unit 68), plasma can be generated only between the cathode intermediate member 76 and the anode units 90 (anodes 67) provided on both sides of the cathode intermediate member 76. That is, it is possible to form films on two substrates W with one cathode unit 68 at the same time. In addition, since the electrode circuit 500 of the electrode unit 31 having the above-mentioned structure is a balanced circuit, uniform plasma can be generated between the cathode intermediate member 76 and the anode units 90. Therefore, since the substrates W are arranged between the cathode intermediate member 76 and the anode units 90, it is possible to form uniform films on the film forming surfaces WO of two substrates W. Further, since the electrode circuit 500 is a balanced circuit, a current flows only between the cathode intermediate member 76 and the anode units 90 and no current theoretically flows between the cathode intermediate member 76 and the inner wall of the film forming chamber 11. Therefore, it is possible to prevent a film from being formed on the inner wall of the film forming chamber 11 without generating a discharge. As a result, it is possible to prevent the generation of particles.

According to the structure in which the electrode circuit 500 is a balanced circuit, even when one of the plurality of electrode units 31 provided in the film forming chamber 11 is not operated due to, for example, a defect, the other electrode units 31 do not break an electrode balance due to the failure of the electrode unit. Therefore, uniform plasma is generated between the cathode intermediate members 76 and the anodes 67 of the other electrode units 31. When a plurality of electrode units 31 is provided in the film forming chamber 11 and films are formed on a plurality of substrates W at the same time, it is possible to form uniform films on the film forming surfaces WO of all of the substrates W.

Since the insulating transformer 202 is provided between the RF power supply 201 and the matching circuit 200, impedance is more than that when the insulating transformer is provided between the matching circuit 200 and the cathode unit 68, and a voltage and a current have the same phase. Therefore, it is possible to reduce the size of the insulating transformer 202.

### Second Embodiment

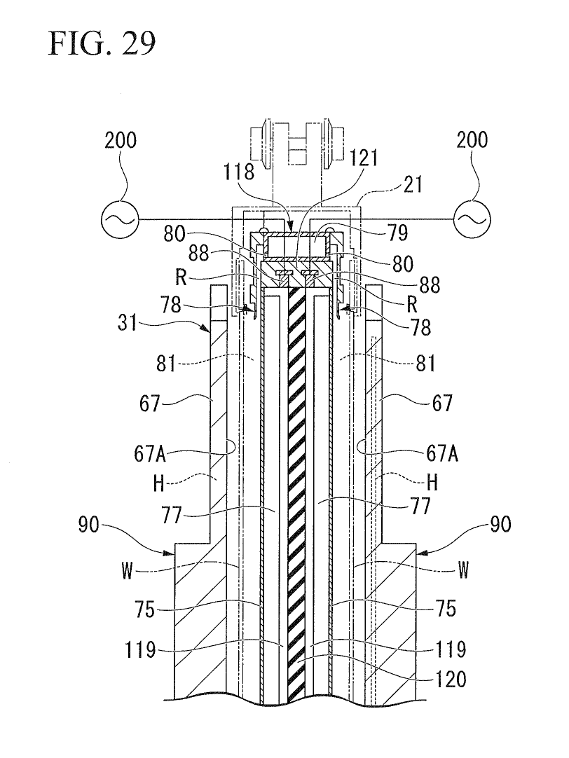

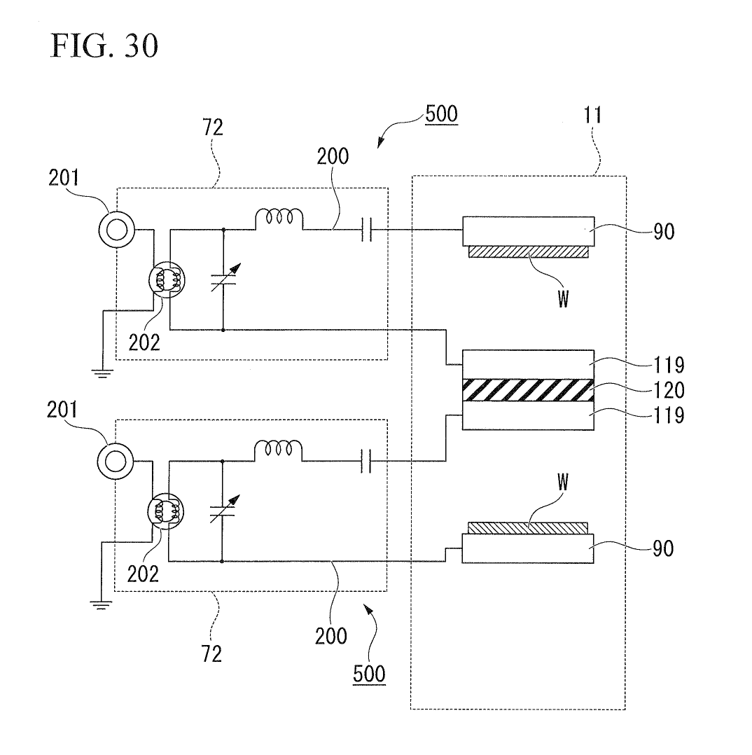

Next, an electrode circuit, an electrode unit, and a film formation device (thin-film solar cell manufacturing apparatus 10) according to a second embodiment of the present invention will be described with reference to FIGS. 29 and 30. This embodiment has substantially the same structure as the first embodiment except for the structure of the cathode unit and the matching circuit. Therefore, the same components as those in the first embodiment are denoted by the same reference numerals and a detailed description thereof will be omitted.

Similar to the thin-film solar cell manufacturing apparatus 10 according to the first embodiment, the thin-film solar cell manufacturing apparatus 10 according to this embodiment includes: film forming chambers 11 that can simultaneously form bottom cells 104 (semiconductor layers) made of microcrystalline silicon on a plurality of substrates W; loading-ejecting chambers 13 that can simultaneously store a pre-processed substrate W1 that is carried into the film forming chamber 11 and a post-processed substrate W2 that is carried out from the film forming chamber 11; substrate replacement chambers 15 that remove the pre-processed substrate W1 and the post-processed substrate W2 from a carrier 21; a substrate replacement robot 17 that removes the substrate W from the carrier 21; and substrate storage holders 19 that store the substrates W to be transported to other processing chambers. Electrode units 31 are removably provided in the film forming chamber 11 and a heater H is provided in an anode 67 of the electrode unit 31. A driving device 71 and a matching box 72 for driving the anodes 67 are attached to a side plate portion 63 of the electrode unit 31. The basic structure of the components are the same as those in the first embodiment (which is the same as that in the following embodiments).

In the thin-film solar cell manufacturing apparatus 10 according to this embodiment, a cathode unit 118 provided between two anodes 67, 67 (two anode units 90, 90) includes an insulating member 120 that has a flat plate shape and is provided substantially at the center in the width direction. A pair of RF applying members (cathodes) 119 is arranged substantially in parallel with the insulating member 120 interposed therebetween. The insulating member 120 is made of, for example, alumina or silica. Each of the pair of RF applying members 119 has a flat plate shape.

A pair of shower plates 75 is provided so as to face the pair of RF applying members 119. Each of the shower plates 75 is arranged so as to come into contact with the edge of one surface of the corresponding RF applying member 119 close to the anode 67. That is, the edge of each shower plate 75 and the edge of each RF applying member 119 are electrically connected to each other. A space 77 for introducing a film forming gas is formed between each shower plate 75 and each RF applying member 119.

Each RF applying member 119 includes a feeding point 88 to which a voltage is applied from the RF power supply (radio frequency power supply) 201 through the matching box 72. Wiring lines are provided between each feeding point 88 and the matching box 72. The feeding points 88 and the wiring lines are surrounded by an insulating member 121 made of, for example, alumina or silica.

FIG. 30 is a circuit diagram illustrating an electrode circuit 500 (matching circuit) according to this embodiment.

As shown in FIG. 30, in the electrode circuit 500 according to this embodiment, one matching box 72 is provided for a set of the RF applying member 119 and the anode unit 90 (anode 67). That is, two matching boxes 72 are provided in one electrode unit 31. According to this structure, each of the matching circuits 200, 200 can adjust a voltage applied from RF power supplies 201 and 201 to the RF applying members 119, 119. Therefore, it is possible to easily adjust the balance between the circuits adjacent to each other with the insulating member 120 interposed therebetween. In this structure, it is preferable to match the phases of the matching circuits 200, 200 using a phase controller in advance.

Therefore, according to the second embodiment, since the insulating member 120 is inserted between two RF applying members (cathode) 119, 119, it is possible to reduce the mutual interference between two electrodes (cathodes), in addition to the effect of the first embodiment.

According to the second embodiment, since the matching box 72 is provided in each of the matching circuits 200, 200, it is possible to easily adjust an electrode balance.

That is, in this embodiment, since the insulating member 120 is provided between a pair of RF applying members 119, 119, voltages are applied to the pair of RF applying members 119, 119 without any interference therebetween. Therefore, discharge occurs in two film formation spaces 81, 81 without any interference therebetween and it is possible to stably form a uniform film. Since the matching box 72 (matching circuit 200) is provided for each set of the RF applying member 119 and the anode unit 90, it is possible to adjust the output of the RF power supply 201 for each matching circuit 200. As a result, it is possible to generate uniform plasma between the RF applying member 119 and the anode unit 90 adjacent to each other with the insulating member 120 interposed therebetween.

### Third Embodiment

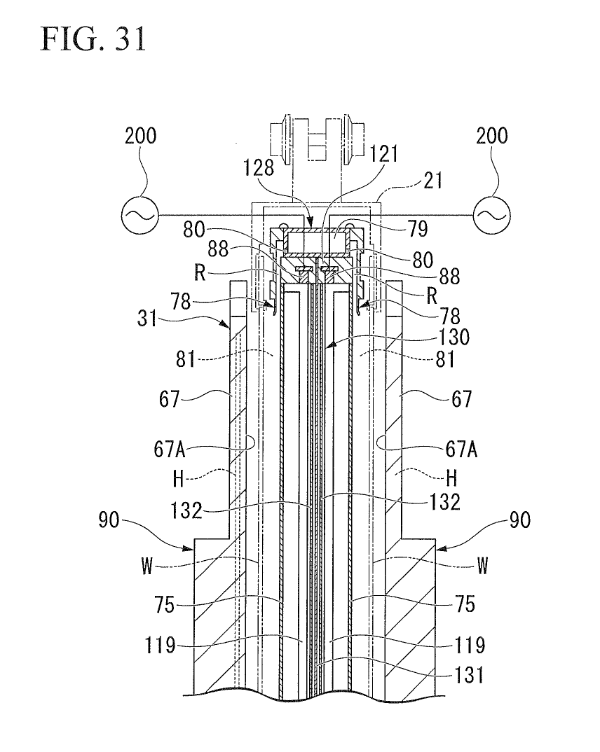

Next, an electrode circuit, an electrode unit, and a film formation device (thin-film solar cell manufacturing apparatus) according to a third embodiment of the present invention will be described with reference to FIG. 31.

The difference between this embodiment and the second embodiment is as follows. In the cathode unit 118 according to the second embodiment, each of a pair of RF applying members 119 is arranged substantially in parallel to the other with the insulating member 120 interposed therebetween. However, in a cathode unit 128 according to this embodiment, each of a pair of cathodes (RF applying members) 119 is arranged substantially in parallel to the other, with an inhibition mechanism (earth shield) 130 that inhibits electrical connection interposed therebetween.

The inhibition mechanism 130 includes a flat earth plate 131 that is provided at the center in the width direction of the cathode unit 128 and a pair of shield plates 132, 132 that is provided on both sides of the earth plate 131.

The earth plate 131 is interposed between a pair of RF applying members 119, 119. The RF applying members 119, 119 and the shield plates 132, 132 are electrically separated by both surfaces of the earth plate 131. That is, both sides of the cathode unit 128 in the width direction are electrically separated by the earth plate 131. Each of the pair of shield plates 132, 132 is interposed between the earth plate 131 and the cathode 119.

Since a predetermined floating capacitance is given to the shield plates 132, 132 provided between the two RF applying members 119, 119 and the earth plate 131, it is possible to prevent the mutual interference between the two RF applying members 119, 119. The floating capacitance can be formed between each of the two RF applying members 119, 119 and the earth plate 131 by the following structure. “1” A dielectric is interposed between the RF applying member 119 and the earth plate 131 or “2” a gap of approximately 1 mm to 29 mm is formed between the RF applying member 119 and the earth plate 131. As the structure for forming the gap, the following structure may be used. (1) Metal plates which electrically float overlap each other with a gap therebetween, or (2) insulating plates overlap each other with a gap therebetween.

According to the third embodiment, since the inhibition mechanism 130 that inhibits electrical connection is provided between a pair of RF applying members 119, voltages are applied to the pair of RF applying members 119 without any interference therebetween, in addition to the effect of the first embodiment.

Therefore, discharge occurs in two film formation spaces 81 without any interference therebetween. In addition, it is possible to individually set the conditions of the film formation spaces 81, 81 formed between the shower plates (cathodes) 75 and the substrates W and individually tune the two substrates W. Therefore, uniform films are stably formed on the two substrates W.

That is, in this embodiment, since the inhibition mechanism 130 is provided between a pair of RF applying members 119, 119, voltages are applied to the pair of RF applying members 119, 119 without any interference therebetween. Therefore, discharge occurs in two film formation spaces 81, 81 without any interference therebetween and it is possible to stably form uniform films on the substrates W. Since the matching box 72 (matching circuit 200) is provided for each set of the RF applying member 119 and the anode unit 90, it is possible to adjust the output of the RF power supply 201 for each matching circuit 200. As a result, it is possible to generate uniform plasma between the RF applying member 119 and the anode unit 90 adjacent to each other with the inhibition mechanism 130 interposed therebetween.

The technical scope of the present invention is not limited to the above-described embodiments, but various modifications or changes of the above-described embodiments can be made without departing from the scope of the present invention. That is, the detailed shapes or structures according to the above-described embodiments are just illustrative and can be appropriately changed.

For example, in the first embodiment, the shower plate (cathode) 75 and the cathode intermediate member 76 are individually provided. However, the present invention is not limited thereto, but the shower plate (cathode) 75 and the cathode intermediate member 76 may be integrally formed.

In the second and third embodiments, the shower plate (cathode) 75 and the RF applying member 119 are individually provided. However, the present invention is not limited thereto, but the shower plate (cathode) 75 and the RF applying member 119 may be integrally formed.

In the above-described embodiments, a film may be formed with the electrode surfaces of the cathode and the anode arranged in parallel to the film forming surface of the substrate W. Therefore, the present invention may be applied to a film formation device that forms a film, with the electrode surfaces of the cathode and the anode and the substrate W arranged at an angle of less than 45 degrees with respect to the horizontal direction, in addition to the film formation device that forms a film, with the electrode surfaces of the cathode and the anode and the substrate W arranged at an angle of less than 45 degrees with respect to the gravity direction as in the first embodiment.

### INDUSTRIAL APPLICABILITY

According to the electrode circuit of the present invention, since a circuit including a matching circuit, parallel plate electrodes, and plasma generated by the parallel plate electrodes is a balanced circuit, a current flows only between the parallel plate electrodes (a pair of an anode electrode and a cathode electrode). As a result, plasma is generated only between the parallel plate electrodes. Therefore, uniform plasma is generated between the parallel plate electrodes and it is possible to form a uniform film on a film forming surface of a substrate.

### DESCRIPTION OF REFERENCE NUMERALS AND SIGNS

10: THIN-FILM SOLAR CELL MANUFACTURING APPARATUS (FILM FORMATION DEVICE)

11: FILM FORMING CHAMBER

31: ELECTRODE UNIT

67: ANODE (ANODE ELECTRODE)

68, 118, 128: CATHODE UNIT (CATHODE ELECTRODE)

75: SHOWER PLATE (CATHODE)

76: CATHODE INTERMEDIATE MEMBER (ELECTRODE UNIT)

78: MASK

90: ANODE UNIT

102: TOP CELL (FILM)

104: BOTTOM CELL (FILM)

119: RF APPLYING MEMBER (CATHODE)

120: INSULATING MEMBER (INSULATOR)

130: INHIBITION MECHANISM (INSULATOR)

200: MATCHING CIRCUIT

201: RF POWER SUPPLY (ALTERNATING-CURRENT SOURCE)

500: ELECTRODE CIRCUIT

W: SUBSTRATE

WO: SURFACE (FILM FORMING SURFACE)

What is claimed is:

1. (canceled)

2. The electrode circuit according to claim 1, wherein: An electrode circuit for plasma CVD comprising:
an alternating-current source;
a matching circuit that is connected to the alternating-current source; and
parallel plate electrodes that are constituted of a pair of an anode electrode and a cathode electrode, in which the anode electrode and the cathode electrode are arranged such that electrode surfaces of the anode electrode and the cathode electrode face each other, wherein the matching circuit, the parallel plate electrodes, and a plasma generated by the parallel plate electrodes form a balanced circuit;
two sets of the parallel plate electrodes are connected to one alternating-current source;
the electrode surfaces of the anode electrodes of the two sets of parallel plate electrodes are arranged in parallel so as to face each other; and
the cathode electrodes of the two sets of parallel plate electrodes are provided between the anode electrodes.

3. The electrode circuit according to claim 2, wherein the electrode surfaces of each of the cathode electrodes of the two sets of parallel plate electrodes are one surface and the other surface of one cathode electrode.

4. (canceled)

5. A film formation device comprising:
a plurality of the electrode circuits according to claim 2 which is provided in one film forming chamber, wherein
in a plurality of the parallel plate electrodes in the plurality of electrode circuits, the electrode surfaces of the anode electrodes are arranged in parallel so as to face each other, and the cathode electrodes of the parallel plate electrodes are provided between the anode electrodes.

6. An electrode unit comprising:
the electrode circuit according to claim 2, wherein the electrode circuit is configured so as to be integrally removable from a film forming chamber.

7. A film formation method using the film formation device according to claim 5, wherein a mask provided at an edge of a substrate is electrically connected to a ground to form a film.

8. A film formation device comprising:
a plurality of the electrode circuits according to claim 3 which is provided in one film forming chamber, wherein the electrode surfaces of the anode electrodes of a plurality of the parallel plate electrodes in the plurality of electrode circuits are arranged in parallel so as to face each other, and the cathode electrodes of the parallel plate electrodes are provided between the anode electrodes.

9. An electrode unit comprising:
the electrode circuit according to claim 3, wherein the electrode circuit is configured so as to be integrally removable from a film forming chamber.

10. A film formation method using the film formation device according to claim 8, wherein a mask provided at an edge of a substrate is electrically connected to a ground to form a film.
